(19) United States
(12) Patent Application Publication
(10) Pub. No.: US 2024/0179994 A1
(43) Pub. Date: May 30, 2024

(54) DISPLAY DEVICE

(71) Applicant: LG Display Co., Ltd., Seoul (KR)

(72) Inventors: Kyung Jae YOON, Paju-si (KR); Hyun Jin AN, Paju-si (KR); Seung Han PAEK, Paju-si (KR); Jeon Phill HAN, Paju-si (KR); Sung Woo JUN, Paju-si (KR)

(73) Assignee: LG Display Co., Ltd., Seoul (KR)

(21) Appl. No.: 18/231,893

(22) Filed: Aug. 9, 2023

(30) Foreign Application Priority Data
Nov. 28, 2022 (KR) 10-2022-0161120

(51) Int. Cl. H10K 59/65; H10K 59/121; H10K 59/124

(52) U.S. Cl. CPC H10K 59/65; H10K 59/121; H10K 59/124

(57) ABSTRACT

A display device may include a display panel including a first display area having a plurality of first pixels and a second display having a plurality of second pixels and a light-transmission area between the second pixels. The display device may further include a sensor or an optical element under the display panel and overlapping with the second display area of the display panel. The display panel may include a substrate, a circuit layer on the substrate and having a buffer layer and a plurality of insulating layers, and a light emitting element layer on the circuit layer. The second display area may include a hole penetrating the substrate, the buffer layer, and the plurality of insulating layers.

### CROSS-REFERENCE TO RELATED APPLICATION

This application claims priority to and the benefit of Korean Patent Application No. 10-2022-0161120, filed Nov. 28, 2022, the disclosure of which is incorporated herein by reference in its entirety.

### BACKGROUND

### 1. Technical Field

The embodiments of the present disclosure relate to a display device.

### 2. Discussion of Related Art

Electroluminescence display devices may be classified into inorganic light-emitting display devices and organic light-emitting displays according to a material of an emission layer. An active matrix organic light-emitting display device includes an organic light-emitting diode (OLED) that generates light by itself and has advantages in terms of a high response rate, high luminous efficiency, high luminance, and a large viewing angle. In an organic light-emitting display device, an OLED is formed at each pixel. The organic light-emitting display device has a high response rate, high luminous efficiency, high luminance, and a large viewing angle and is capable of expressing black gradation in perfect or near perfect black, thereby achieving a high contrast ratio and a high color reproduction rate.

Multi-media functions of mobile terminals are being improved. For example, a camera is built into a smart phone, and the resolution of the built-in camera is increasing to the level of a conventional digital camera. However, a front camera of the smart phone limits the screen design, thereby making it more difficult to design the screen with a front camera incorporated. To reduce the space occupied by the camera, a screen design including a notch or punch hole has been adopted for smart phones. However, the screen size is still limited due to the notch or punch hole, thereby making it difficult to implement a full-screen display.

To implement a full-screen display, methods of providing an imaging area in which low-resolution pixels are disposed within the screen of the display panel and disposing electronic components, such as cameras and various sensors, to face the imaging area under the display panel are being proposed.

However, since pixels are disposed in the imaging area, light transmissivity is lowered due to these pixels. Thus, the performance of the camera and/or various sensors may be adversely affected.

### SUMMARY

Accordingly, embodiments of the present disclosure are directed to a display device that substantially obviates one or more problems due to the limitations and disadvantages of the related art.

An embodiment of the present disclosure provides a display device including a structure in which the light transmissivity is improved in an area where a sensor is disposed.

An embodiment of the present disclosure provides a display device in which a high-transmittance area is formed by removing a portion or all of a substrate corresponding to a sensor or an optical element to improve the light transmissivity.

An embodiment of the present disclosure provides a display device in which the substrate is formed as a single layer.

An embodiment of the present disclosure provides a display device in which a high-transmittance area is formed by removing a portion of a circuit layer corresponding to a sensor or an optical element to improve the light transmissivity.

An embodiment of the present disclosure provides a display device in which a portion or all of a glass plate corresponding to a sensor or an optical element is removed to improve the light transmissivity or a high-transmittance area is formed by leaving only a portion of the glass plate through an etching process.

Objectives and features of embodiments of the present disclosure are not limited to those described above. Additional objectives and features will be set forth in part in the description that follows and in part will become apparent to those skilled in the art from the description or may be learned by practice of the inventive concepts provided herein. Other features and aspects of the inventive concepts may be realized and attained by the structure particularly pointed out in, or derivable from, the written description, the claims hereof, and the appended drawings.

To achieve these and other advantages and in accordance with the purpose of the disclosure, as embodied and broadly described herein, a display device may include: a display panel including a first display area having a plurality of first pixels and a second display having a plurality of second pixels and a light-transmission area between the second pixels; and a sensor or an optical element under the display panel and overlapping with the second display area of the display panel, wherein the display panel may include a substrate, a circuit layer on the substrate and having a buffer layer and a plurality of insulating layers, and a light emitting element layer on the circuit layer, and wherein the second display area may include a hole penetrating the buffer layer, and the plurality of insulating layers.

In some example embodiments, the hole may further penetrate the substrate, and the second display area of the display panel may further include a glass disposed under the substrate only in the second display area to cover the hole.

In some example embodiments, the display device may further include a back plate disposed at a bottom surface of the substrate to cover a bottom surface of the glass.

In some example embodiments, the glass may include a first surface in contact with the substrate and a second surface opposite to the first surface and facing the sensor or the optical element, and the second surface may include a predetermined pattern or have a concave profile.

In some example embodiments, the circuit layer may further include a first planarization layer on the plurality of insulating layers, and a same material forming the first planarization layer may be disposed in the hole.

In some example embodiments, the hole may have a tapered cross section with a wider opening at a top of the hole than at a bottom of the hole.

In some example embodiments, the substrate may have one or more first grooves penetrating a bottom surface of the substrate, the one or more first grooves overlapping with the hole.

In some example embodiments, the substrate may cover the hole at a top surface of the substrate, and a portion of the substrate may be disposed between the hole and the one or more first grooves so that the hole is spaced apart from the one or more first grooves.

In some example embodiments, the display panel may further include an organic material or an inorganic material in the one or more first grooves of the substrate. The organic material may include at least one of an epoxy-based material including epoxy, polyimide, polyethylene terephthalate, polycarbonate, polyethylene, polyacrylate, and an acrylic-based material. The inorganic material may include at least one of silicon oxide (SiOx), silicon nitride (SiNx), silicon oxynitride (SiON), aluminum oxide (AlO), aluminum nitride (AlON), titanium oxide (TiO2), zirconium oxide (ZrOx), and zinc oxide (ZnO).

In some example embodiments, the display device may further include a glass plate at the bottom surface of the substrate.

In some example embodiments, the glass plate may include a second groove penetrating at least a bottom surface of the glass plate in the second display area, the second groove overlapping with the hole and the one or more first grooves.

In some example embodiments, the substrate may be formed of one single layer.

In some example embodiments, the sensor or the optical element may be an image sensor or a lens of a camera module.

In some example embodiments, a resolution of the second pixels in the second display area may be lower than a resolution of the first pixels in the first display area.

In another aspect of the present disclosure, a display device may include: a display panel including a first display area having a plurality of first pixels and a second display area having a plurality of second pixels and a light-transmission area between the second pixels; and a sensor or an optical element under the display panel and overlapping with the second display area of the display panel. Here, the display panel may include: a substrate including a low-transmittance area and a high-transmittance area having higher light transmissivity than the low-transmittance area in the second display area, the substrate having a hole or at least one first groove penetrating at least a bottom surface of the substrate in the high-transmittance area; a circuit layer on the substrate; and a light emitting element layer on the circuit layer.

In some example embodiments, the display panel may further include an organic material or an inorganic material in the hole or the at least one first groove of the substrate. The organic material may include at least one of an epoxy-based material including epoxy, polyimide, polyethylene terephthalate, polycarbonate, polyethylene, polyacrylate, and an acrylic-based material. The inorganic material may include at least one of silicon oxide (SiOx), silicon nitride (SiNx), silicon oxynitride (SiON), aluminum oxide (AlO), aluminum nitride (AlON), titanium oxide (TiO2), zirconium oxide (ZrOx), and zinc oxide (ZnO).

In some example embodiments, the display device may further include a glass plate at the bottom surface of the substrate between the substrate and the sensor or the optical element.

In some example embodiments, the glass plate may include a first glass plate area overlapping with the low-transmittance area, and a second glass plate area overlapping with the high-transmittance area and having a second groove penetrating at least a bottom surface of the glass plate, the second glass plate area having a smaller thickness than the first glass plate area.

In some example embodiments, the glass plate may include a first glass plate area overlapping with the low-transmittance area and a second glass plate area overlapping with the high-transmittance area and having a hole through the glass plate, the second glass area having a minimum thickness of 0.

In some example embodiments, the substrate may be formed of one single layer.

In some example embodiments, the sensor or the optical element may be an image sensor or a lens of a camera module.

In some example embodiments, a resolution of the second pixels in the second display area may be lower than a resolution of the first pixels in the first display area.

According to example embodiments of the present disclosure, the light transmissivity of a second display area may be improved by implementing a high-transmittance structure, such as a hole or a groove formed in a substrate. Furthermore, where a camera module is disposed in the second display area, the quality of a captured image, such as color, may be improved through the high-transmittance structure. That is, by removing a portion or all of the substrate disposed in a portion of the imaging area corresponding to a camera module, the function of recognizing the object (e.g., a face) to be captured may be performed with improved light transmissivity and improved camera performance.

According to an example embodiment, the flexibility of the display panel may be improved by disposing a glass disposed under a substrate only in an imaging area. In addition, according to the embodiment, since a thickness of the glass may be minimized through an etching process, the light transmissivity through the glass may be improved.

According to an example embodiment, since a glass plate is molded through etching, a single-layer PI substrate may be used. Accordingly, by minimizing the thickness of the substrate, flexibility of the display device may be improved, and the light transmissivity of the second display area may be improved.

According to an example embodiment, the light transmissivity may be further improved by removing a portion of a circuit layer in the second display area corresponding to a sensor or an optical element.

According to an example embodiment, the light transmissivity may be further improved by removing a portion or all of a glass plate in the second display area corresponding to a sensor or an optical element.

According to an example embodiment, a low-power driving is possible by improving the light transmissivity through a high-transmittance structure.

In addition to the various features, aspects, and advantages of the present disclosure described above, other features, aspects, and advantages of the present disclosure will be described below or may be clearly understood by those skilled in the art from such description or explanation. It is to be understood that both the foregoing general description and the following detailed description of the present disclosure are by way of example and are intended to provide further explanation of the disclosures as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a conceptual diagram of a display device according to an example embodiment of the present disclosure;

FIGS. 2A to 2D are diagrams illustrating various arrangement positions and shapes of a second display area of a display panel according to example embodiments of the present disclosure;

FIG. 3 is a schematic cross-sectional view of a display panel according to an example embodiment of the present disclosure;

FIG. 4 is a diagram illustrating example pixels arranged in a first display area of a display panel according to an example embodiment of the present disclosure;

FIG. 5A is a diagram illustrating pixels and light-transmission areas disposed in a second display area of a display panel according to an example embodiment of the present disclosure;

FIG. 5B is an enlarged view of a portion A in FIG. 5A;

FIG. 6 is a diagram schematically illustrating an example structure of a display panel in a second display area;

FIG. 7 is a modified example of FIG. 6;

FIGS. 8A and 8B are diagrams showing various example polarizing plate structures;

FIG. 9 is a diagram illustrating a display panel and a display panel driver according to an example embodiment of the present disclosure;

FIG. 10 is a circuit diagram illustrating an example of a pixel circuit;

FIG. 11 is a diagram schematically illustrating a display device according to a comparative example;

FIG. 12 is a diagram schematically illustrating a display device according to a first example embodiment of the present disclosure;

FIG. 13 is a cross-sectional view illustrating in detail a cross-sectional structure of a pixel area in a display panel according to an example embodiment of the present disclosure;

FIG. 14 is a diagram illustrating cross-sectional structures of a pixel area and a light-transmission area of a display device according to a first example embodiment of the present disclosure;

FIGS. 15A to 15D are diagrams illustrating a manufacturing method of a glass disposed in the display device according to the first example embodiment;

FIGS. 16A to 16C are diagrams illustrating various example shapes of glass disposed on a display panel according to an example embodiment of the present disclosure;

FIG. 17 is a diagram schematically illustrating a display device according to a second example embodiment of the present disclosure;

FIG. 18 is a diagram illustrating cross-sectional structures of a pixel area and a light-transmission area of a display device according to a second example embodiment of the present disclosure;

FIGS. 19 to 21 are diagrams illustrating various modified examples of a light-transmission area of a display device according to a second example embodiment of the present disclosure;

FIG. 22 is a diagram schematically illustrating a display device according to a third example embodiment of the present disclosure;

FIG. 23 is a diagram illustrating cross-sectional structures of a pixel area and a light-transmission area of a display device according to a third example embodiment of the present disclosure;

FIG. 24 is a diagram illustrating a modified example of a glass plate disposed in a light-transmission area of a display device according to a third example embodiment of the present disclosure;

FIG. 25 is a diagram illustrating another example of a hole formed in a substrate of a display device according to a third example embodiment of the present disclosure;

FIG. 26 is a view showing another example of a hole formed in a substrate of a display device and a modified example of a glass plate disposed to correspond to the hole according to a third example embodiment of the present disclosure;

FIG. 27 is a diagram schematically illustrating a display device according to a fourth example embodiment of the present disclosure;

FIG. 28 is a diagram illustrating cross-sectional structures of a pixel area and a light-transmission area of a display device according to a fourth example embodiment of the present disclosure;

FIG. 29 is a diagram illustrating a modified example of a glass plate disposed in a light-transmission area of a display device according to a fourth example embodiment of the present disclosure;

FIG. 30 is a diagram illustrating another example of a groove formed in a substrate of a display device according to a fourth example embodiment of the present disclosure;

FIG. 31 is a view showing another example of a groove formed in a substrate of a display device and a modified example of a glass plate disposed to correspond to the groove according to a fourth example embodiment of the present disclosure; and

FIGS. 32A and 32B are pictures illustrating a flare of a display device according to a comparative example and a flare of a display device according to an example embodiment of the present disclosure.

### DETAILED DESCRIPTION

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. The same or similar elements are designated by the same reference numerals throughout the specification unless otherwise specified.

In the following description, where the detailed description of the relevant known function or configuration may unnecessarily obscure an important point of the present disclosure, a detailed description of such known function or configuration may be omitted.

Where the terms “comprise,” “have,” “include,” and the like are used, one or more other elements may be added unless the term, such as “only,” is used. An element described in the singular form is intended to include a plurality of elements, and vice versa, unless expressly stated otherwise or the context clearly indicates otherwise.

In construing an element, the element is to be construed as including an ordinary error or tolerance range even where no explicit description of such an error or tolerance range is provided.

Where positional relationships are described, for example, where the positional relationship between two parts is described using “on,” “over,” “under,” “above,” “below,” “beside,” “next to,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” and the like may be used herein to describe various elements, the elements should not be limited by these terms as they are not used to define, for example, a particular order, precedence, or number of the corresponding elements. These terms are used only to identify one element from another. For example, a first element could be termed a second element, and similarly, a second element could be termed a first element, without departing from the scope of the present disclosure.

The same reference numerals may refer to substantially the same elements throughout the present disclosure unless otherwise specified.

Features of various embodiments of the present disclosure may be partially or entirely coupled to or combined with each other. They may be linked and operated technically in various ways as those skilled in the art can sufficiently understand. The embodiments may be carried out independently of or in association with each other in various combinations.

Reference will now be made in detail to embodiments of the present disclosure, examples of which may be illustrated in the accompanying drawings.

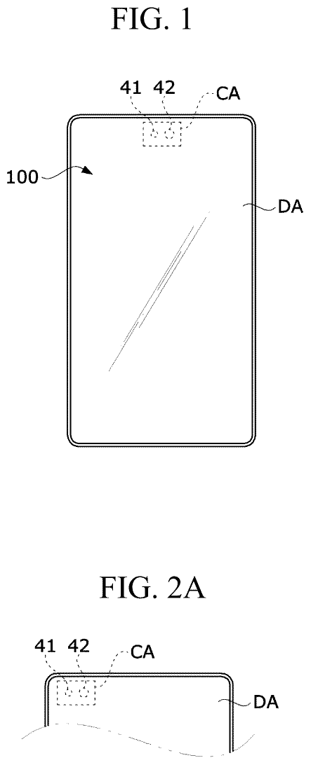

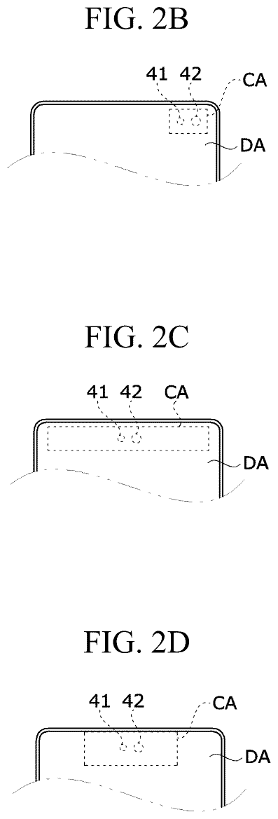

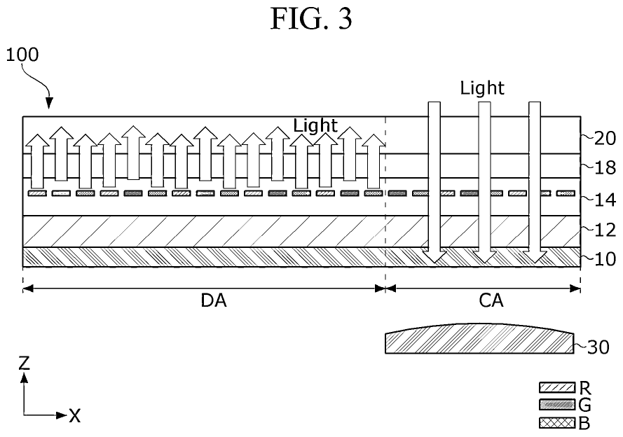

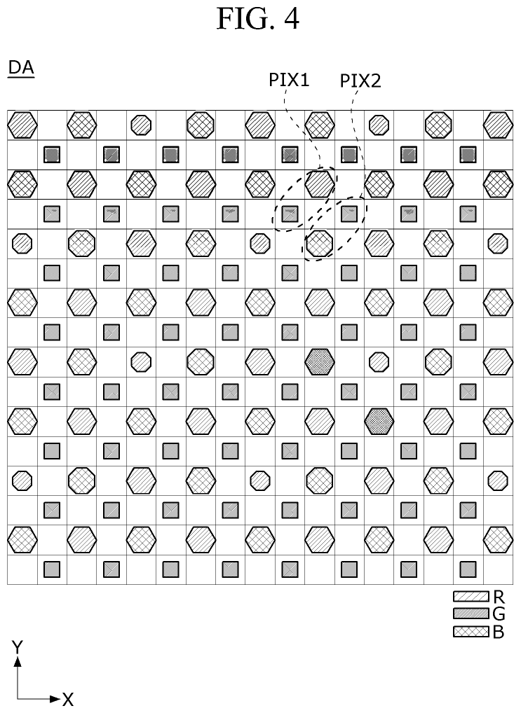

FIG. 1 is a conceptual diagram of a display device according to an example embodiment of the present disclosure. FIGS. 2A to 2D are diagrams illustrating various arrangement positions and shapes of a second display area of a display panel according to example embodiments of the present disclosure. FIG. 3 is a schematic cross-sectional view of a display panel according to an example embodiment of the present disclosure. FIG. 4 is a diagram illustrating example pixels arranged in a first display area of a display panel according to an example embodiment of the present disclosure.

As illustrated in FIG. 1, a display device according to an example embodiment of the present disclosure may include a display panel 100 and a case. The front surface of the display panel 100 may be implemented with a display area. Accordingly, the display device may implement a full-screen display.

The display area may include a first display area DA and a second display area CA. Here, both the first display area DA and the second display area CA may output images but may have different resolutions. For example, the resolution of the plurality of second pixels disposed in the second display area CA may be lower than the resolution of the plurality of first pixels disposed in the first display area DA. A sufficient amount of light may be injected into the sensors 41 and 42 disposed in the second display area CA in correlation with an amount of reduction in resolution of the plurality of second pixels disposed in the second display area.

However, the example embodiment is not necessarily limited thereto. If the second display area CA has sufficient light transmissivity or an appropriate noise compensation algorithm can be implemented, the resolution of the first display area DA and the resolution of the second display area CA may be the same.

The second display area CA may be an area where the sensors 41 and 42 are disposed. Since the second display area CA may be an area overlapping with various sensors, it may have a smaller area than the first display area DA, which may output most of the image.

The sensors 41 and 42 may include at least one of an image sensor, a proximity sensor, an illuminance sensor, a gesture sensor, a motion sensor, a fingerprint recognition sensor, and a biometric sensor. For example, the first sensor 41 may be an illuminance sensor, and the second sensor 42 may be an image sensor that captures images or videos, but the sensors are not limited thereto.

As illustrated in FIGS. 2A to 2D, the second display area CA may be disposed at various positions where light is incident. For example, the second display area CA may be disposed at an upper left side of the display area, as shown in FIG. 2A. In addition, as shown in FIG. 2B, the second display area CA may be disposed on the upper right side of the display area. Further, as shown in FIG. 2C, the second display area CA may be disposed across nearly the entire width at the top of the display area. In addition, as shown in FIG. 2D, the width of the second display area CA may be variously modified. However, the position of the second display area CA is not necessarily limited to the example positions shown in FIGS. 2A to 2D. For example, the second display area CA may be disposed in the center or lower end of the display area.

Hereinafter, the first display area DA may be described as a display area and the second display area CA may be described as an imaging area.

As shown in FIGS. 3 and 4, the display area DA and the imaging area CA may each include a pixel array in which pixels are disposed, and pixel data may be written to the pixels. The number of pixels per inch (PPI) of the imaging area CA may be lower than that of the display area DA to secure sufficient light transmissivity of the imaging area CA.

The pixel array of the display area DA may include a pixel area (a first pixel area) in which a plurality of pixels having a high PPI are disposed. In addition, the pixel array of the imaging area CA may include a pixel area (a second pixel area) in which a plurality of pixel groups having a relatively low PPI are disposed due to being spaced apart by one or more light-transmission areas. In the imaging area CA, an external light may pass through the display panel 100 through the light-transmission areas having high light transmissivity and may be transmitted to a sensor under the display panel 100.

Since both the display area DA and the imaging area CA include pixels, an input image may be reproduced on the display area DA and the imaging area CA.

Each of the pixels of the display area DA and the imaging area CA may include sub-pixels having different colors to implement the color of an image. The sub-pixels may include a red sub-pixel (hereinafter referred to as an “R sub-pixel”), a green sub-pixel (hereinafter referred to as a “G sub-pixel”), and a blue sub-pixel (hereinafter referred to as a “B sub-pixel”). Although not shown, each of the pixels P may further include a white sub-pixel (hereinafter referred to as a “W sub-pixel”). Each of the sub-pixels may include a pixel circuit and a light emitting element (e.g., OLED).

The imaging area CA may include pixels and a camera module disposed under the screen of the display panel 100. The pixels of the imaging area CA may display the input image by writing pixel data of the input image in the display mode.

The camera module may capture an external image in an imaging mode and output photo or moving image data. A lens 30 of the camera module may face the imaging area CA. In addition, the external light may be incident to the lens 30 of the camera module through the imaging area CA, and the lens 30 may concentrate light onto an image sensor (not shown in the drawings). Accordingly, the camera module may output photo or moving image data by capturing an external image in the imaging mode.

To secure the light transmissivity, some pixels may be removed from the imaging area CA compared to the display area DA. In addition, a picture quality compensation algorithm may be applied to the display device to compensate for the luminance and color coordinates of the pixels disposed in the imaging area CA due to the removed pixels.

In the present disclosure, low-resolution pixels may be disposed in the imaging area CA. Therefore, since the display area DA of the screen is not limited due to the camera module, a full-screen display may be implemented.

The display panel 100 has a width in the X-axis direction, a length in the Y-axis direction, and a thickness in the Z-axis direction. Here, the width and length of the display panel 100 may be set to various design values depending on application fields of the display device. In addition, the X-axis direction may mean a width direction or a horizontal direction, the Y-axis direction may mean a longitudinal direction or a vertical direction, and the Z-axis direction may mean a vertical direction, a stacking direction, or a thickness direction. Here, the X-axis direction, the Y-axis direction, and the Z-axis direction may be perpendicular to each other, but may also mean different directions that are not necessarily perpendicular to each other. Accordingly, each of the X-axis direction, the Y-axis direction, and the Z-axis direction may be described as one of a first direction, a second direction, and a third direction. Further, the plane extended in the X-axis direction and the Y-axis direction may mean a horizontal plane.

The display panel 100 may include a circuit layer 12 disposed on the substrate 10 and a light emitting element layer 14 disposed on the circuit layer 12. In addition, the display panel 100 may include a polarizing plate 18 disposed on the light emitting element layer 14 and a cover glass 20 disposed on the polarizing plate 18.

The substrate 10 may be formed of an insulating material or a material having flexibility. For example, the substrate 10 may be made of glass, metal, or plastic, but is not limited thereto.

The circuit layer 12 may include a pixel circuit connected to wirings, such as data lines, gate lines, and power lines, a gate driver connected to the gate lines, and other circuit elements. Further, the circuit layer 12 may include transistors implemented with thin film transistors (TFTs) and circuit elements, such as capacitors or the like. Here, the wirings and circuit elements of the circuit layer 12 may be implemented with a plurality of insulating layers, two or more metal layers separated with the insulating layer(s) interposed therebetween, and an active layer including a semiconductor material.

The light emitting element layer 14 may include a light emitting element driven by a pixel circuit. Here, the light emitting element may be implemented with an organic light emitting diode (OLED). The OLED may include an organic compound layer formed between an anode and a cathode. The organic compound layer may include a hole injection layer (HIL), a hole transport layer (HTL), an emission layer (EMIL), an electron transport layer (ETL), and an electron injection layer (EIL), but is not limited thereto. When a voltage is applied to an anode and a cathode of the OLED, the holes passing through the hole transport layer (HTL) and the electrons passing through the electron transport layer (ETL) may be moved to the light emitting layer (EMIL) to form excitons and emit visible light from the light emitting layer (EMIL).

The light emitting element layer 14 may be disposed on pixels selectively transmitting wavelengths of red, green, and blue lights, and may further include a color filter array.

The light emitting element layer 14 may be covered by a protective layer, and the protective layer may be covered by an encapsulation layer. Here, the protective layer and the encapsulation layer may have a structure in which an organic film and an inorganic film are alternately stacked. In this case, the inorganic film may block penetration of moisture or oxygen. In addition, the organic film may planarize the surface of the inorganic film. If the organic film and the inorganic film are stacked in multiple layers, a movement path of moisture or oxygen is longer than that in a single layer. Accordingly, the penetration of moisture or oxygen affecting the light emitting element layer 14 may be effectively blocked or mitigated.

A polarizing plate 18 may be adhered on the encapsulation layer covering the light emitting layer 14. The polarizing plate 18 may improve outdoor visibility of the display device. The polarizing plate 18 may reduce light reflected from the surface of the display panel 100 and block light reflected from the metal of the circuit layer 12 to improve the brightness of the pixels. The polarizing plate 18 may be implemented with a polarizing plate in which a linear polarizing plate and a phase retardation film are bonded together or with a circular polarizing plate.

As shown in FIG. 4, the display area DA may include pixels PIX1 and PIX2 arranged in a matrix form. Each of the pixels PIX1 and PIX2 may be implemented with a real-type pixel in which R, G, and B sub-pixels of three primary colors are configured as one pixel.

Each of the pixels PIX1 and PIX2 may further include a W sub-pixel omitted from the drawings. In addition, two sub-pixels may be configured as one pixel by using a sub-pixel rendering algorithm. For example, the first unit pixel PIX1 may be composed of R and G sub-pixels, and the second unit pixel PIX2 may be composed of B and G sub-pixels. Insufficient color representation in each of the pixels PIX1 and PIX2 may be compensated for by an average value of corresponding color data between pixels adjacent to each other.

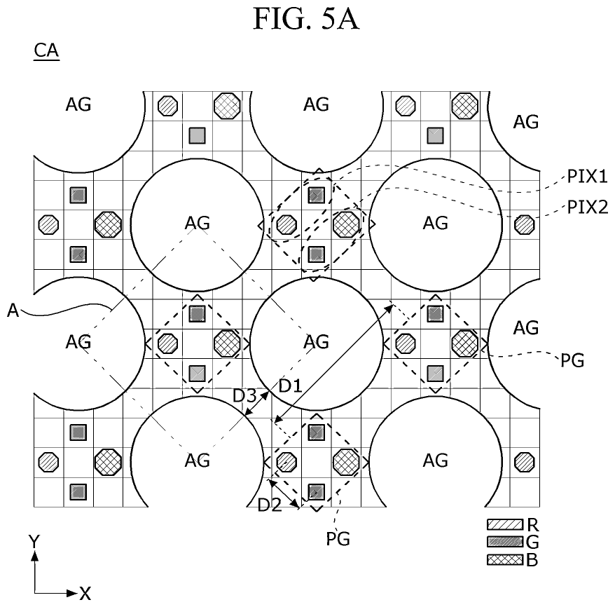

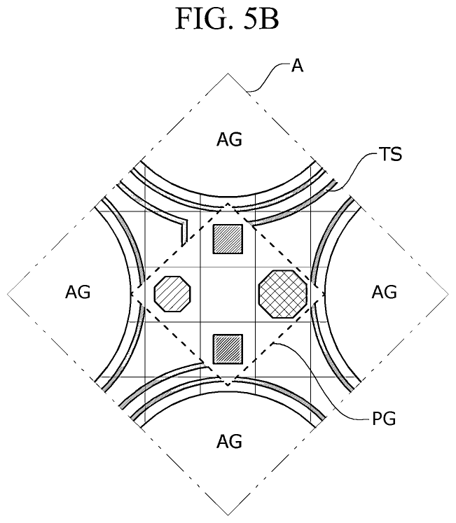

FIG. 5A is a diagram illustrating pixels disposed and light-transmission areas in a second display area of a display panel according to an example embodiment of the present disclosure. FIG. 5B is an enlarged view of a portion Ain FIG. 5A.

As illustrated in FIGS. 5A and 5B, a plurality of light-transmission area areas AG may be disposed between a plurality of second pixels. In detail, an imaging area CA may include pixel groups PG spaced apart by a predetermined distance D1 (between respective centers of adjacent pixel groups) and the light-transmission area(s) AG disposed between the pixel groups PG adjacent to each other. The external light may be received by a lens of the camera module through the light-transmission areas AG. The pixel groups PG may be spaced apart from each other within the pixel area.

The light-transmission areas AG may include transparent materials having high light transmissivity without metal so that light may pass through with minimal light loss. The light-transmission areas AG may be made of transparent insulating materials without including metal wirings or pixels. Accordingly, the light transmissivity of the imaging area CA may increase as the light-transmission areas AG are larger.

One or two pixels may be included in a pixel group PG. Each of the pixels of the pixel group PG may include two to four sub-pixels. For example, one pixel in the pixel group PG may include R, G, and B sub-pixels or two sub-pixels, and may further include a W sub-pixel.

A distance D3 between the light-transmission areas AG may be smaller than an interval (pitch) D1 between the pixel groups PG. An interval D2 between sub-pixels (between respective centers of adjacent sub-pixels) may be smaller than the interval D1 between the pixel groups PG.

The shape of the light-transmission areas AG is illustrated as circular but is not limited thereto. For example, the light-transmission areas AG may be designed in various shapes, such as a circular shape, an elliptical shape, and a polygonal shape, among others.

All of the metal electrode material may be removed in the light-transmission area AG. Accordingly, the wirings TS of the pixels may be disposed outside the light-transmission areas AG. Therefore, light may effectively pass through the light-transmission area AG. However, the present disclosure is not necessarily limited thereto, and a metal electrode material may remain in some areas of the light-transmission areas AG.

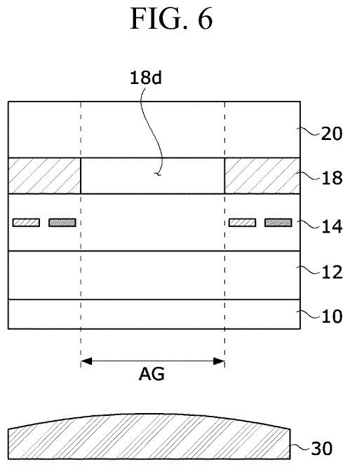

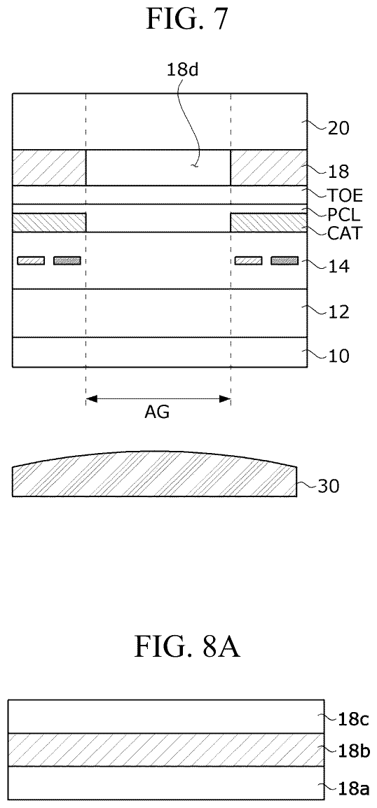

FIG. 6 is a diagram schematically illustrating an example structure of a display panel in an imaging area, and FIG. 7 is a modified example of FIG. 6.

As shown in FIG. 6, the display panel may include a circuit layer 12 disposed on a substrate 10 and a light emitting element layer 14 disposed on the circuit layer 12. Further, a polarizing plate 18 may be disposed on the light emitting element layer 14, and a cover glass 20 may be disposed on the polarizing plate 18.

In the polarizing plate 18, a first light-transmission pattern 18d may be formed in an area corresponding to the light-transmission area AG. Based on the green light of 555 nm, the light transmissivity of the substrate made of polyimide (PI) is about 70% to 80%, and the light transmissivity of the cathode electrode is about 80% to 90%. In contrast, the light transmissivity of the polarizing plate 18 may be relatively very low at about 40%. Therefore, the light transmissivity of the polarizing plate 18 may need to be increased to effectively increase the light transmissivity in the light-transmission area AG.

The light transmissivity of the polarizing plate 18 may be improved forming a first light-transmission pattern 18d on the light-transmission area AG. The light transmissivity of an area where the first light-transmission pattern 18d is formed may be higher than that of the other areas of the polarizing plate 18. Accordingly, since the amount of light introduced into the camera module is increased in the light-transmission area AG, camera performance may be improved.

The first light-transmission pattern 18d of the polarizing plate 18 may be formed by removing a portion of the polarizing plate 18 or by decomposing a compound constituting the polarizing plate 18. That is, various structures capable of increasing the light transmissivity of the existing polarizing plate 18 may be applied to the first light-transmission pattern 18d.

As illustrated in FIG. 7, in the light-transmission area AG, the polarizing plate 18 may have a first light-transmission pattern 18d and the cathode electrode CAT may have a second light-transmission pattern. The second light-transmission pattern may be an opening formed in the cathode electrode CAT in the light-transmission area. Since the light transmissivity of the cathode electrode CAT may be about 80% to 90%, the light transmissivity in the light-transmission area AG may be further increased by the opening in the cathode electrode CAT.

The method of forming the opening in the cathode electrode CAT is not particularly limited. Illustratively, after forming the cathode electrode, an etching process may be used to form an opening in the cathode electrode CAT, or an IR laser may be irradiated from the lower portion of the substrate 10 to remove a portion of the cathode electrode CAT.

A planarization layer PCL may be formed on the cathode electrode CAT, and a touch sensor TOE may be disposed thereon. In this case, the sensing electrode and wiring of the touch sensor in the light-transmission area AG may be made of a transparent material (for example, ITO or metal mesh) to increase light transmissivity.

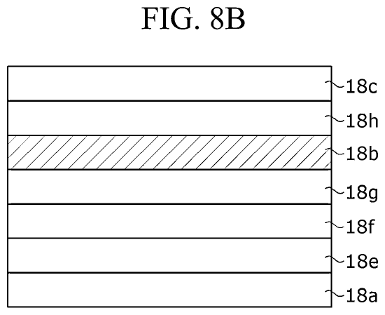

FIGS. 8A and 8B are diagrams showing various example polarizing plate structures.

As shown in FIG. 8A, the polarizing plate 18 may include a first protective layer 18a, a second protective layer 18c, and a polarizing plate 18b disposed between the first protective layer 18a and the second protective layer 18c.

The polarizing plate 18b may include a dichroic material. The dichroic material may include at least one of iodine and organic dyes. The organic dyes may include, for example, azo-based pigments, stilbene-based pigments, pyrazolone-based pigments, triphenylmethane-based pigments, quinoline-based pigments, oxazine-based pigments, thiazine-based pigments, and anthraquinone-based pigments, but are not necessarily limited thereto.

The polarizing plate 18b may have a light-transmission axis perpendicular to the stretching direction. Since iodine molecules and dye molecules show dichroism, they may have functions of absorbing light vibrating in the stretching direction and transmitting light vibrating in the vertical direction.

The polarizing plate 18b may have low mechanical strength in the direction of the light-transmission axis, and may be contracted or have its polarization function deteriorated by heat or moisture. The first and second protective layers 18a and 18c are for protecting the polarizing plate 18b without changing the characteristics of light transmitted through the polarizing plate 18b, and may be formed by using triacetyl cellulose (TAC) as an example. The TAC has high light transmissivity, relatively low birefringence, and easy hydrophilization by surface modification, so that it may be easily laminated with the polarizing plate 18b.

As illustrated in FIG. 8B, various functional layers 18e, 18f, 18g, and 18h may be additionally disposed above and below the polarizing plate 18b in the polarizing plate 18. For example, the functional layers 18e, 18f, 18g, and 18h may include pressure sensitive adhesive (PSA), quarter wave plate (QWP), and hard coating (HC). However, most of the layers constituting the polarizing plate 18 may have relatively high light transmissivity compared to the polarizing plate 18b. Therefore, controlling the light transmissivity of the polarizing plate 18b may be important for increasing the light transmissivity of the light-transmission area AG.

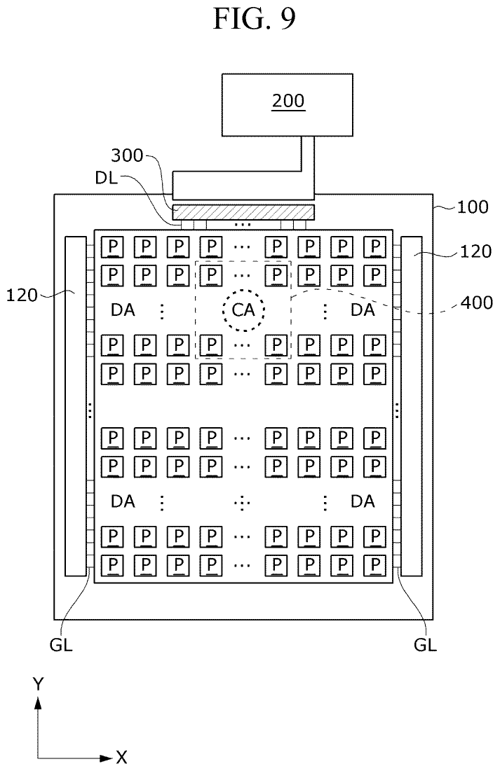

FIG. 9 is a diagram illustrating a display panel and a display panel driver according to an example embodiment of the present disclosure.

As shown in FIG. 9, the example display device may include a display panel 100 having a pixel array disposed on a screen and a display panel driver, among other elements.

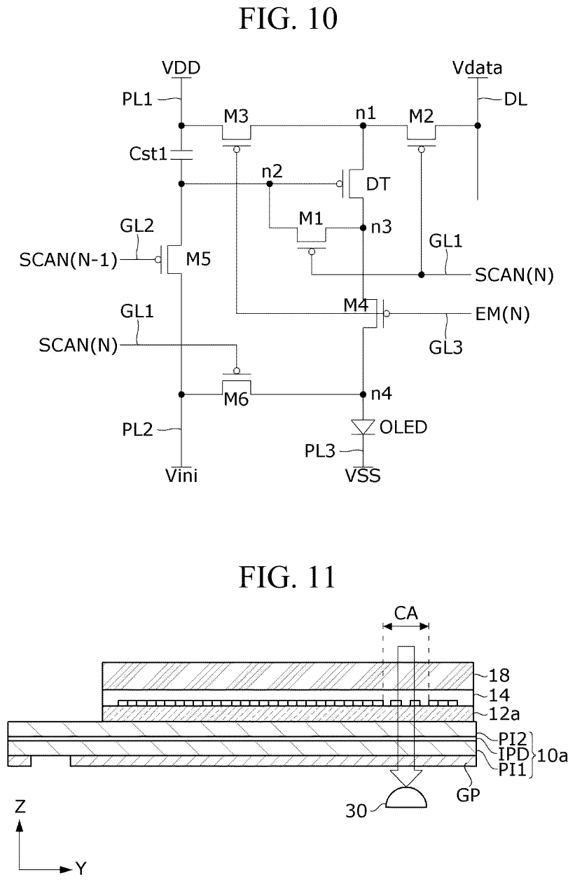

The pixel array of the display panel 100 may include data lines DL, gate lines GL crossing the data lines DL, and pixels P connected to data lines DL and the gate lines GL and arranged in a matrix form. The pixel array may further include power wirings, such as VDD line PL1, Vini line PL2, and VSS line PL3 shown in FIG. 10.

The pixel array may be divided into a circuit layer 12 and a light emitting element layer 14 as shown in FIG. 2. Further, a touch sensor array may be disposed on the light emitting element layer 14. Here, each of the pixels of the pixel array may include two to four sub-pixels as described above. Each of the sub-pixels may include a pixel circuit disposed on the circuit layer 12.

A screen on which an input image is reproduced on the display panel 100 may include a display area DA and an imaging area CA.

Each of the sub-pixels of the display area DA and the imaging area CA may include a pixel circuit. The pixel circuit may include a driving element for supplying current to the light emitting element OLED, a plurality of switch elements for sampling the threshold voltage of the driving element and for switching the current path of the pixel circuit, and a capacitor for maintaining the gate voltage of the driving element, among other elements. In this case, the pixel circuit may be disposed below the light emitting element.

The imaging area CA may include light-transmission areas AG disposed between pixel groups and a camera module 400 disposed under the imaging area CA. The camera module 400 may photoelectrically convert light incident through the imaging area CA using an image sensor in an imaging mode, convert pixel data of an image outputted from the image sensor into digital data, and output captured image data.

The display panel driver may write pixel data of an input image into the pixels P. The pixels P may be interpreted as a pixel group including a plurality of sub-pixels.

The display panel driver may include a data driver for supplying a data voltage of pixel data to the data lines DL and a gate driver 120 for sequentially supplying gate pulses to the gate lines GL. Further, the data driver may be integrated into a drive IC 300. In addition, the display panel driver may further include a touch sensor driver (not shown in the drawings).

The drive IC 300 may be bonded on the display panel 100. The drive IC 300 may receive pixel data of an input image and a timing signal from a host system 200, supply a data voltage of the pixel data to the pixels, respectively, and synchronize the data driver and the gate driver 120.

The drive IC 300 may be connected to the data lines DL through data output channels to supply data voltages of pixel data to the data lines DL. The drive IC 300 may output a gate timing signal for controlling the gate driver 120 through gate timing signal output channels.

The gate driver 120 may include a shift register formed on a circuit layer of the display panel 100 together with a pixel array. The shift register of the gate driver 120 may sequentially supply gate signals to the gate lines GL under the control of the timing controller. The gate signal may include a scan pulse and an EM pulse of an emission signal.

The host system 200 may be implemented with an application processor (AP). The host system 200 may transmit pixel data of an input image to the drive IC 300 through a mobile industry processor interface (MIPI). The host system 200 may be connected to the drive IC 300 through a flexible printed circuit, for example, a flexible printed circuit (FPC).

In addition, the display panel 100 may be implemented with a flexible panel applicable to a flexible display.

The flexible panel may be made of a so-called “plastic OLED panel.” The plastic OLED panel may include a back plate and a pixel array on an organic thin film adhered on the back plate. A touch sensor array may be formed over the pixel array.

The back plate may be a polyethylene terephthalate (PET) substrate. The pixel array and the touch sensor array may be formed on the organic thin film. The back plate may block moisture permeation toward the organic thin film so that the pixel array is not exposed to humidity.

The organic thin film may be a polyimide (PI) substrate. A multi-layered buffer film may be formed on the organic thin film with an insulating material (not shown). Further, the circuit layer 12 and the light emitting element layer 14 may be stacked on the organic thin film.

In the display device according to example embodiments of the present disclosure, a pixel circuit and a gate driver disposed on the circuit layer 12 may include a plurality of transistors. The transistors may be implemented with, for example, oxide thin film transistors (TFTs) including an oxide semiconductor and low temperature polysilicon (LTPS) TFTs including low temperature polysilicon, among others. In addition, each of the transistors may be implemented as a p-channel TFT or an n-channel TFT.

A transistor is a three-electrode element including a gate, a source, and a drain. The source is an electrode that may provide carriers to the transistor. The carriers in the transistor may start to flow from the source. The drain is an electrode through which the carriers may be discharged externally from the transistor.

In the transistor, carriers may flow from the source to the drain. In the case of an n-channel transistor, carriers are electrons. Thus, a source voltage may be lower than a drain voltage so that the electrons flow from the source to the drain. In the n-channel transistor, current may flow from the drain to the source.

In the case of a p-channel transistor (PMOS), carriers are holes. Thus, a source voltage may be higher than a drain voltage so that the holes flow from the source to the drain. In the p-channel transistor, since the holes flow from the source to the drain, current may flow from the source to the drain. It should be noted that the source and drain of the transistor are not necessarily fixed. For example, the source and drain may be interchangeable depending on the applied voltage. Accordingly, the present disclosure is not limited by the source and drain of the transistor. In the following description, the source and the drain of the transistor will be referred to as a first electrode and a second electrode, one of which may be a source and the other may be a drain.

A gate pulse may swing between a gate-on voltage and a gate-off voltage. The gate-on voltage may be set to be higher than a threshold voltage of the transistor, and the gate-off voltage may be set to be lower than the threshold voltage of the transistor.

The transistor may be turned on in response to the gate-on voltage and may be turned off in response to the gate-off voltage. In the case of an n-channel transistor, the gate-on voltage may be a gate-high voltage VGH, and the gate-off voltage may be a gate-low voltage VGL. In the case of a p-channel transistor, the gate-on voltage may be a gate-low voltage VGL, and the gate-off voltage may be a gate-high voltage VGH.

A driving element of the pixel circuit may be implemented with a transistor. The electrical characteristics of the driving element should be uniform among all pixels. However, there may be differences in the electrical characteristics between the pixels due to a process variation and element characteristic variation, and the electrical characteristics may change as a display driving time accumulates.

To compensate for variations in electrical characteristics of the driving elements, the display device may include an internal compensation circuit and an external compensation circuit. The internal compensation circuit may be added to the pixel circuit in each of the sub-pixels to sample the threshold voltage (Vth) and/or mobility (μ) of the driving element, which may vary depending on electrical characteristics of the driving element, and to compensate for the variation in real time.

The external compensation circuit may transmit a threshold voltage and/or mobility of the driving element sensed through a sensing line connected to each of the sub-pixels to an external compensation circuit. The compensation part of the external compensation circuit may compensate for a change in electrical characteristics of the driving element by modulating pixel data of an input image based on a sensing result.

A voltage of each pixel that varies depending on electrical characteristics of an external compensation driving element may be sensed. Then, input image data may be modulated in an external circuit based on the sensed voltage such that a deviation in electrical characteristics of a driving element between pixels may be compensated for.

FIG. 10 is a circuit diagram illustrating one example of a pixel circuit.

The example pixel circuit shown in FIG. 10 may be equally applied to the pixel circuits of a display area DA and an imaging area CA.

As shown in FIG. 10, the pixel circuit may include a light emitting element OLED, a driving element DT for supplying current to the light emitting element OLED, and an internal compensation circuit for sampling the threshold voltage Vth of the driving element DT and compensating for the gate voltage of the driving element DT by the threshold voltage Vth of the driving element DT using a plurality of switch elements M1 to M6. Each of the driving element DT and the switch elements M1 to M6 may be implemented as a p-channel TFT.

The light emitting element OLED may include an organic compound layer formed between an anode and a cathode. The organic compound layer may include, but is not limited to, a hole injection layer (HIL), a hole transport layer (HTL), a light emitting layer (EML), an electron transport layer (ETL), and an electron injection layer (EIL), among others. When a voltage is applied to the anode and cathode electrodes of the OLED, holes passing through the hole transport layer (HTL) and electrons passing through the electron transport layer (ETL) may be moved to the light emitting layer (EML) to form excitons, and the visible light may be emitted from the light emitting layer (EML).

The anode electrode of the light emitting element OLED may be connected to a fourth node n4 between the fourth and sixth switch elements M4 and M6. The fourth node n4 may be connected to the anode of the light emitting element OLED, a second electrode of the fourth switch element M4, and a second electrode of the sixth switch element M6. The cathode electrode of the light emitting element OLED may be connected to VSS line PL3 to which the low potential power supply voltage VSS is applied. The light emitting element OLED may emit light with the current Ids flowing depending on the gate-source voltage Vgs of the driving element DT. A current path of the light emitting element OLED may be switched by the third and fourth switch elements M3 and M4.

A storage capacitor Cst1 may be connected between the VDD line PL1 and the second node n2. A data voltage Vdata compensated for by the threshold voltage Vth of the driving element DT may be charged in the storage capacitor Cst1. Since the data voltage Vdata in each of the sub-pixels is compensated for by the threshold voltage Vth of the driving element DT, a characteristic deviation of the driving element DT in the sub-pixels may be compensated for.

The first switch element M1 may be turned on in response to a gate-on voltage VGL of an N-th scan pulse SCAN(N) to connect the second node n2 and the third node n3. The second node n2 may be connected to a gate electrode of the driving element DT, a first electrode of the storage capacitor Cst1, and a first electrode of the first switch element M1. The third node n3 may be connected to the second electrode of the driving element DT, the second electrode of the first switch element M1, and a first electrode of the fourth switch element M4. The gate electrode of the first switch element M1 may be connected to a first gate line GL1 to receive the N-th scan pulse SCAN(N). The first electrode of the first switch element M1 may be connected to the second node n2, and the second electrode of the first switch element M1 may be connected to the third node n3.

The first switch element M1 may be turned on only during one very short horizontal period (1H) in which the N-th scan pulse SCAN(N) is generated as the gate-on voltage VGL in one frame period and may otherwise maintain a turned-off state for the remainder of the one frame period. For this reason, a leakage current may be generated in the turned-off state of the first switch element M1.

The second switch element M2 may be turned on in response to the gate-on voltage VGL of the N-th scan pulse SCAN(N) to supply the data voltage Vdata to the first node n1. The gate electrode of the second switch element M2 may be connected to the first gate line GL1 to receive the N-th scan pulse SCAN(N). A first electrode of the second switch element M2 may be connected to the first node n1. The second electrode of the second switch element M2 may be connected to the data line DL to which the data voltage Vdata is applied. The first node n1 may be connected to the first electrode of the second switch element M2, the second electrode of the third switch element M2, and the first electrode of the driving element DT.

The third switch element M3 may be turned on in response to the gate-on voltage VGL of the light emitting signal EM(N) to connect the VDD line PL1 to the first node n1. The gate electrode of the third switch element M3 may be connected to the third gate line GL3 to receive the light emitting signal EM(N). A first electrode of the third switch element M3 may be connected to the VDD line PL1. A second electrode of the third switch element M3 may be connected to the first node n1.

The fourth switch element M4 may be turned on in response to the gate-on voltage VGL of the light emitting signal EM(N) to connect the third node n3 to the anode of the light emitting element OLED (or to the fourth node n4). The gate electrode of the fourth switch element M4 may be connected to the third gate line GL3 to receive the light emitting signal EM(N). The first electrode of the fourth switch element M4 may be connected to the third node n3, and the second electrode thereof may be connected to the fourth node n4.

The fifth switch element M5 may be turned on in response to the gate-on voltage VGL of the (N−1)th scan pulse SCAN(N−1) to connect the second node n2 to the Vini line PL2. The gate electrode of the fifth switch element M5 may be connected to the second gate line GL2 to receive the (N−1)th scan pulse SCAN(N−1). The first electrode of the fifth switch element M5 may be connected to the second node n2, and the second electrode thereof may be connected to the initialization voltage Vini line PL2.

The sixth switch element M6 may be turned on in response to the gate-on voltage VGL of the N-th scan pulse SCAN(N) to connect the initialization voltage Vini line PL2 to the fourth node n4. The gate electrode of the sixth switch element M6 may be connected to the first gate line GL1 to receive the N-th scan pulse SCAN(N). A first electrode of the sixth switch element M6 may be connected to the initialization voltage Vini line PL2, and a second electrode thereof may be connected to the fourth node n4.

The driving element DT may drive the light emitting element OLED by adjusting the current Ids flowing through the light emitting element OLED depending on the gate-source voltage Vgs. The driving element DT may include a gate connected to the second node n2, a first electrode connected to the first node n1, and a second electrode connected to the third node n3.

FIG. 11 is a diagram schematically illustrating a display device according to a comparative example.

As illustrated in FIG. 11, the display device according to the comparative example may include a circuit layer 12a disposed on a substrate 10a, a light emitting element layer 14 disposed on the circuit layer 12a, a polarizing plate 18 disposed on light emitting element layer 14, and a glass plate GP disposed below the substrate 10a.

If a material such as polyimide is used as the substrate 10a of the display device according to the comparative example, the performance of the camera module may suffer due to a yellowish color.

Furthermore, in order to prevent potential defects due to a laser lift off (LLO) process, the display device according to the comparative example essentially includes a double PI substrate structure, and this double PI substrate structure increases the thickness of the substrate. Accordingly, the transmissivity of light reaching the camera module in the second display area CA is further reduced. Here, the double PI substrate may include a first PI substrate PI1, a second PI substrate PI2, and an inorganic film (IPD) disposed between the first PI substrate PI1 and the second PI substrate PI2. Thus, the thickness of the double PI substrate in the Z-axis direction may be approximately 22 μm.

Accordingly, due to the material of the PI substrate and the dual PI substrate structure for the laser lift off (LLO) process, the display device according to the comparative example has a relatively low transmissivity in the second display area CA. Thus, the display device according to the comparative example has structural limitations regarding the light transmissivity, such as difficulty in using a face recognition function.

Therefore, the display device according to example embodiments of the present disclosure may include a high-transmittance structure for improving a light-transmittance property in the second display area CA to secure a greater amount of light reaching the sensors 41 and 42. Accordingly, the display device according to example embodiments of the present disclosure may overcome limitations of quality deterioration due to the low transmissivity and yellowish color from the use of such material as polyimide in the second display area CA.

Accordingly, the display device according to example embodiments of the present disclosure may improve a light-transmittance property in the second display area CA by presenting various examples of a high-transmittance structure that improve the light-transmittance property.

Hereinafter, a display device according to various example embodiments of the present disclosure will be described.

### First Example Embodiment

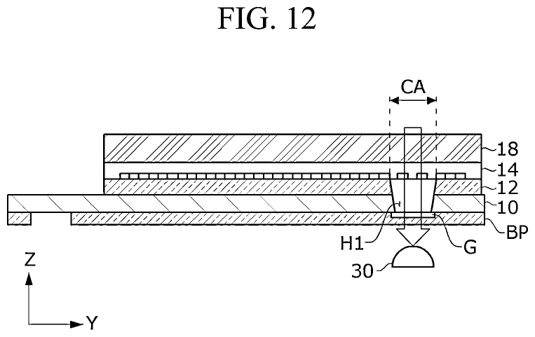

FIG. 12 is a diagram schematically illustrating a display device according to a first example embodiment of the present disclosure.

As illustrated in FIG. 12, a display device according to a first example embodiment of the present disclosure may include a circuit layer 12 disposed on a substrate 10, a light emitting element layer 14 disposed on the circuit layer 12, a polarizing plate 18 disposed on the light emitting element layer 14 and a hole H1 formed to penetrate the substrate 10 and the circuit layer 12 in the Z-axis direction. Accordingly, the display device according to the first example embodiment of the present disclosure may implement a high-transmittance structure that improves a light-transmittance property through the hole H1. In this case, the hole H1 may be formed to have a tapered cross section, and a transparent organic or inorganic material may be disposed therein. Here, the hole H1 may be referred to as a first hole or a first high-transmittance structure.

In addition, the display device according to the first example embodiment may include glass G disposed to cover one side of the hole H1. The glass G may be formed by etching the glass plate GP supporting the substrate 10. Accordingly, the glass G may prevent the circuit layer 12 and the light emitting element layer 14 from being damaged by an etching process. In addition, the glass G may support an organic or inorganic material disposed inside the hole H1. In this case, the area of the glass G on the horizontal plane may be larger than the area of the hole H1.

In addition, the display device according to the first example embodiment may further include a back plate BP disposed below the substrate 10, and the back plate BP may be disposed to cover the glass G.

In addition, since the glass G may be formed in the display device according to the first example embodiment while most of the glass plate GP is removed through an etching process rather than a laser lift-off (LLO) process, the substrate 10 of the display device according to the first example embodiment of the present disclosure may be formed of one single layer. Accordingly, since the thickness of the substrate 10 in the Z-axis direction may be reduced compared to that of the substrate 10a of the comparative example, the light transmissivity of the display device according to the first example embodiment may be improved. Here, the thickness of the substrate 10 in the Z-axis direction may be approximately 10 μm.

Therefore, by implementing the hole H1 and the single PI substrate structure, the display device according to the first example embodiment may improve the light transmissivity by about 3.7% compared to the comparative example.

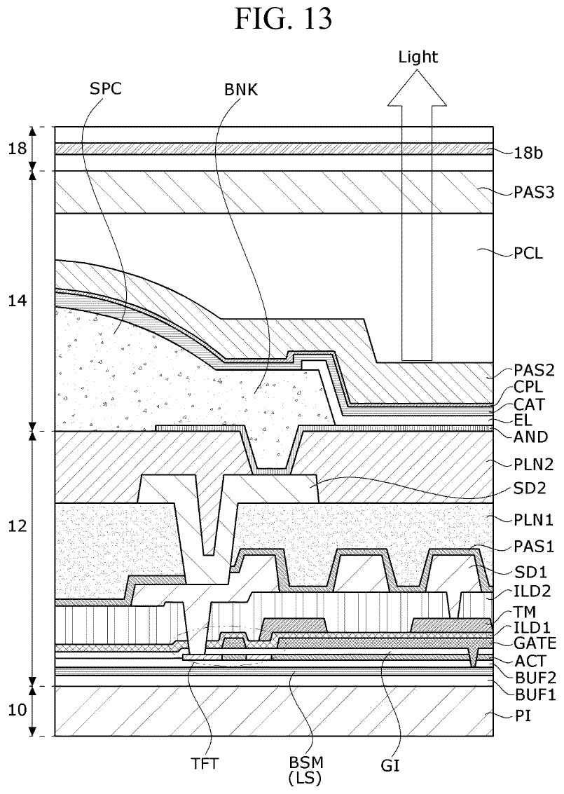

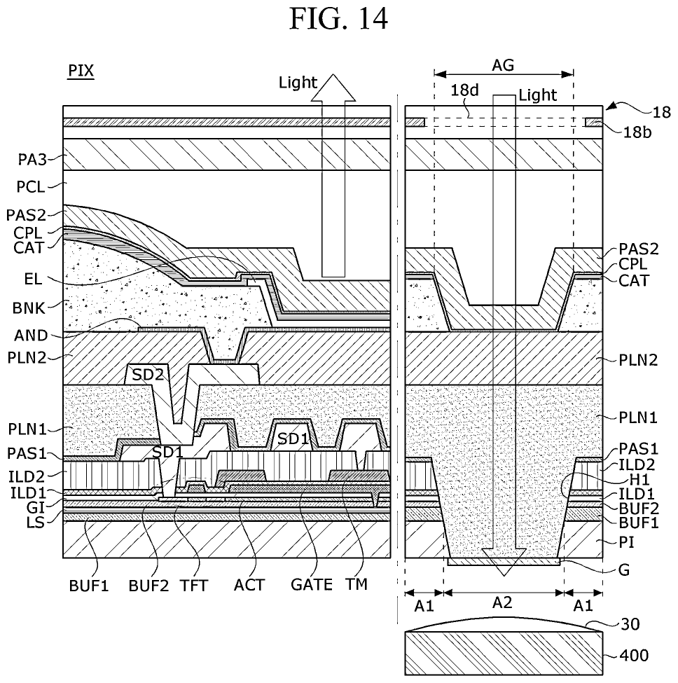

FIG. 13 is a cross-sectional view illustrating in detail an example cross-sectional structure of a pixel area in a display panel according to an example embodiment of the present disclosure. FIG. 14 is a diagram illustrating example cross-sectional structures of a pixel area and a light-transmission area of a display device according to a first example embodiment of the present disclosure. Here, the cross-sectional structure of the display panel 100 is not limited to that illustrated in FIG. 13. In addition, a TFT shown in FIG. 13 represents an example driving element DT of a pixel circuit.

As shown in FIG. 13, a circuit layer 12, a light emitting element layer 14, and other layers or elements may be stacked on the substrate 10 in the pixel area PIX.

The substrate 10 may be formed of one single layer and may be formed of such material as polyimide PI. Here, since the substrate PI is formed of one single layer, it may be formed to a smaller thickness than the substrate 10a of the display device of the comparative example. Accordingly, the adverse effect of the substrate PI on the light transmissivity may be reduced. Further, the substrate PI may be referred to as a PI substrate.

The first buffer layer BUF1 may be formed on the substrate PI. A first metal layer may be formed on the first buffer layer BUF1, and a second buffer layer BUF2 may be formed on the first metal layer.

The first metal layer may be patterned in a photolithography process. The first metal layer may include a light shield pattern BSM. The light shield pattern BSM may block external light so that light is not irradiated to an active layer of the TFT. Accordingly, a photo current of the TFT formed in the pixel area may be prevented.

If the light shield pattern BSM is formed of a metal having a lower absorption coefficient of the laser wavelength used in the laser ablation process compared to a metal layer (for example, a cathode electrode) to be removed from the imaging area CA, the light shield pattern BSM may serve as a light shield layer LS for blocking a laser beam in a laser ablation process. That is, the light shield layer LS may protect the pixel P from the laser beam irradiated onto the display panel 100 in the laser ablation process.

Each of the first and second buffer layers BUF1 and BUF2 may be formed of an inorganic insulating material and may be composed of one or more insulating layers.

The active layer ACT may be formed of a semiconductor material deposited on the second buffer layer BUF2 and patterned through a photo-lithography process. The active layer ACT may include active patterns of the TFTs of the pixel circuit and the TFTs of the gate driver. A portion of the active layer ACT may be metalized by ion doping. The metalized portion may be used as a jumper pattern connecting metal layers at some nodes of the pixel circuit to connect various components of the pixel circuit.

The gate insulating layer GI may be formed on the second buffer layer BUF2 to cover the active layer ACT. The gate insulating layer GI may be made of an inorganic insulating material.

The second metal layer may be formed on the second gate insulating layer GI. The second metal layer may be patterned by a photo-lithography process. The second metal layer may include, among others, a gate line and gate electrode pattern GATE, a lower electrode of the storage capacitor Cst1, and a jumper pattern connecting patterns of the first metal layer and the third metal layer.

A first interlayer insulating layer ILD1 may be formed on the gate insulating layer GI to cover the second metal layer. A third metal layer may be formed on the first interlayer insulating layer ILD1, and a second interlayer insulating layer ILD2 may cover the third metal layer. The third metal layer may be patterned by a photo-lithography process. The third metal layer may include, for example, the same metal patterns TM as an upper electrode of the storage capacitor Cst1. The first and second interlayer insulating layers ILD1 and ILD2 may include an inorganic insulating material.

A fourth metal layer may be formed on the second interlayer insulating layer ILD2, and an inorganic insulating layer PAS1 and a first planarization layer PLN1 may be stacked thereon. A fifth metal layer may be formed on the first planarization layer PLN1.

A portion of the pattern of the fourth metal layer may be connected to the third metal layer through a contact hole penetrating the first planarization layer PLN1 and the inorganic insulating layer PAS1. The first and second planarization layers PLN1 and PLN2 may be formed of an organic insulating material for flattening surfaces.

The fourth metal layer may include, for example, first and second electrodes of the TFT connected to the active pattern of the TFT through a contact hole penetrating the second interlayer insulating layer ILD2. For example, a data line DL and power lines PL1, PL2, and PL3 may be implemented with a pattern SD1 of the fourth metal layer or a pattern SD2 of the fifth metal layer.

An anode electrode AND, which is the first electrode layer of the light emitting device OLED, may be formed on the second planarization layer PLN2. The anode electrode AND may be connected to an electrode of a TFT used as a switch element or a driving element through a contact hole penetrating the second planarization layer PLN2. The anode electrode AND may be made of a transparent or translucent electrode material.

A pixel definition layer BNK may cover the anode electrode AND of the light emitting element OLED. The pixel definition layer BNK may be formed in a pattern defining an emission area (or an opening area) through which light may pass externally from each pixel. A spacer SPC may be formed on the pixel definition layer BNK. The pixel definition layer BNK and the spacer SPC may be integrated with the same organic insulating material. The spacer SPC may allow for securing a gap between a fine metal mask (FMM) and the anode electrode AND so that the FMM may not contact the anode electrode AND during the deposition process of the organic compound EL. Here, the pixel definition layer BNK may be referred to as a bank.

An organic compound EL may be formed in an emission area of each of the pixels defined by the pixel definition layer BNK. A cathode electrode CAT, which is the second electrode layer of the light emitting element OLED, may be formed to cover the pixel definition layer BNK, the spacer SPC, and the organic compound EL. The cathode electrode CAT may be connected to the VSS line PL3 formed of one of metal layers below the cathode electrode CAT. A capping layer CPL may cover the cathode electrode CAT. The capping layer CPL may be formed of an inorganic insulating material and may protect the cathode electrode CAT by blocking the penetration of air and out gassing of the organic insulating material applied on the capping layer CPL. An inorganic insulating layer PAS2 may cover the capping layer CPL, and a planarization layer PCL may be formed on the inorganic insulating layer PAS2. The planarization layer PCL may include an organic insulating material. An inorganic insulating layer PAS3 of the encapsulation layer may be formed on the planarization layer PCL.

The polarizing plate 18 may be disposed on the inorganic insulating layer PAS3 to improve outdoor visibility of the display device. The polarizing plate 18 may reduce light reflected from the surface of the display panel 100 and may block light reflected from the metal of the circuit layer 12 to improve the brightness of the pixels.

As illustrated in FIG. 14, a first light-transmission pattern 18d may be formed on the polarizing plate 18 in the light-transmission area AG. The first light-transmission pattern 18d may be formed by discoloring the polarizing plate 18b by a laser or may be formed by partially removing the polarizing plate 18b.

An opening may be formed in the cathode electrode CAT in the light-transmission area AG. Such an opening may be formed by forming the cathode electrode CAT on the pixel definition layer BNK and then etching the cathode electrode CAT and the pixel definition layer BNK at once. Alternatively, the opening may be formed by removing a portion of the cathode electrode CAT with a laser. Here, the opening formed in the cathode electrode CAT may be referred to as a first opening.

Therefore, a groove may be formed in the pixel definition layer BNK, and an opening of the cathode electrode CAT may be formed on the groove. However, the present disclosure is not necessarily limited thereto, and the pixel definition layer BNK may not be formed in the light-transmission area AG, and the cathode electrode CAT may be disposed on the second planarization layer PLN2.

In this case, since the first light-transmission pattern 18d is formed in the polarizing plate 18 in the light-transmission area AG and the first opening is formed to overlap with the first light-transmission pattern 18d in the cathode electrode, the light transmissivity may be improved. Accordingly, a sufficient amount of light may be introduced into the camera module 400, and the camera performance may be improved. As a result, noise of captured image data may also be reduced.

A hole H1 penetrating a portion of the circuit layer 12 and the substrate PI may be formed in the light-transmission area AG. Here, the hole H1 may be called a first hole or a second opening, and may be disposed to overlap with the first opening.

Since the hole H1 is formed to penetrate the buffer layer and the plurality of insulating layers of the circuit layer 12, an interface between the plurality of layers may be omitted by the hole H1, such that the light transmissivity of the light-transmission area AG may be improved.

In addition, the hole H1 penetrating the buffer layer and the plurality of insulating layers of the circuit layer 12 may be extended to penetrate the substrate PI. Accordingly, the second display area CA of the substrate PI may include a low-transmittance area A1 in which a hole H1 is not disposed and a high-transmittance area A2 in which the hole H1 is disposed. Further, the high-transmittance area A2 may be formed through a process of etching the substrate PI. Here, the high-transmittance area A2 may have higher light transmissivity than the low-transmittance area A1, and the low-transmittance area A1 may be referred to as a first area and the high-transmittance area A2 may be referred to as a second area.

Therefore, even if yellowish polyimide is used as the material of the substrate PI, the light transmissivity in the light-transmission area AG may be improved by the high-transmittance area A2.

In addition, a transparent organic or inorganic material may be disposed inside the hole H1. Here, the organic or inorganic material may be the same material as one or more of the layers constituting a first pixel or a second pixel, that is, the first buffer layer BUF1, the second buffer layer BUF2, the gate insulating layer GI, the first interlayer insulating layer ILD1, the second interlayer insulating layer ILD2, the first planarization layer PLN1, the second planarization layer PLN2, among others, or may be a different material. In this case, the organic material and/or inorganic material may be formed through a process of filling the inside of the hole H1.

As shown in FIG. 14, the same material (organic insulating material) forming the first planarization layer PLN1 of the pixel area PIX disposed in the second display area CA may be disposed inside the hole H1. A material implementing the first planarization layer PLN1 may have higher transmissivity than a material implementing the substrate PI. Here, the material disposed inside the hole H1 may be made of an organic insulating material like the first planarization layer PLN1, as an example, but is not necessarily limited thereto. For example, in some cases, the material disposed inside the hole H1 may be an inorganic insulating material.

In addition, the hole H1 may be formed to have a tapered vertical cross section. As shown in FIG. 14, the hole H1 may be formed in a positively tapered shape having a wide top and a narrow bottom.

Meanwhile, a glass G may be disposed below the substrate PI to cover the lower side of the hole H1. In this case, the glass G may be disposed to overlap with the light-transmission area AG.

The glass G is disposed in the second display area CA to cover the hole H1, and may support the organic or inorganic material.

The glass G may be formed by selectively etching a portion of the glass plate GP. In addition, the glass G may be formed to have a thickness smaller than that of the substrate PI through an etching process.

Furthermore, since the display device according to the first example embodiment forms the glass G while removing most of the glass plate GP through an etching process, the substrate PI may be formed as a single layer. Accordingly, the thickness of the substrate PI of the display device according to the first example embodiment may be reduced or minimized compared to the comparative example.

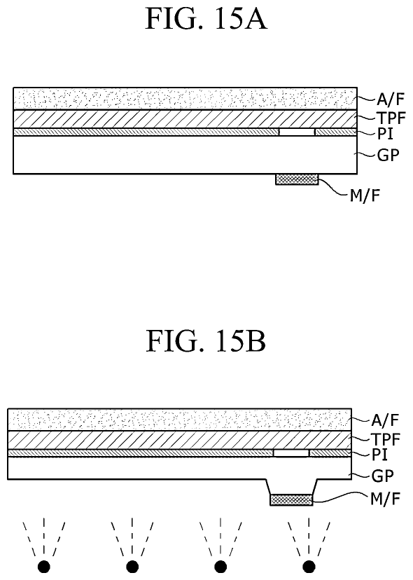

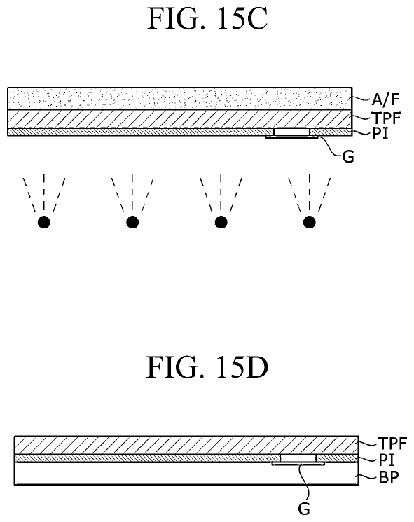

FIGS. 15A-15D illustrate a manufacturing method of a glass G disposed in the display device according to the first example embodiment.

As illustrated in FIGS. 15A-15D, a method of manufacturing a glass G disposed in the display device according to the first example embodiment may include attaching an acid-resistant film A/F and a mask film M/F to a structure composed of a glass plate GP and a substrate PI (FIG. 15A), primary etching (FIG. 15B), removing the mask film M/F and secondary etching (FIG. 15C), and removing the acid-resistant film A/F and attaching a back plate BP (FIG. 15D).

As shown in FIG. 15A, an acid-resistant film A/F and a mask film M/F may be attached to a structure composed of a glass plate GP and a substrate PI. In this case, the mask film M/F may be attached to only a portion of the glass plate GP and may be disposed to correspond to the high-transmittance area A2 of the substrate PI forming the hole H1. Further, a temporary protective layer TPF may be disposed between the acid-resistant film A/F and the substrate PI. Here, the acid-resistant film A/F may be formed using polypropylene (PP), polyethylene (PE), teflon, or a fluororesin-based material. In addition, the temporary protective layer TPF may be formed of polyethylene terephthalate (PET).

As shown in FIG. 15B, in the primary etching process, the glass plate GP may be etched within a range of 10 to 100 m by spraying an etchant on the glass plate GP.

As shown in FIG. 15C, in removing the mask film M/F and secondary etching, the mask film M/F may be removed, and then the glass plate GP may be etched so that only the glass G of about 10 m is left. Accordingly, the glass G may be disposed on the substrate PI to cover one side of the hole H1.

As shown in FIG. 15D, in removing an acid-resistant film A/F and attaching a back plate BP, the acid-resistant film A/F disposed on the upper portion of the temporary protective layer TPF may be removed, and then the back plate BP may be attached to the lower portion of the substrate PI. Accordingly, the back plate BP may support the substrate PI while preventing the glass G from being separated from the substrate PI.

Therefore, in the display panel 100 of the display device according to the first example embodiment, the glass G may be disposed to correspond to the high-transmittance area A2 through selective etching. Further, since most of the glass plate GP is removed through selective etching instead of a laser lift-off (LLO) process, the display device according to the first example embodiment may use the substrate PI formed of a single layer.

In addition, the glass G may be formed in various shapes to improve the concentrating property of light reaching the lens 30 of the camera module 400. For example, the light transmissivity of the glass G may be improved by variously changing the shape of a back surface, which is one surface of the glass G, to prevent obliquely incident light from being totally reflected.

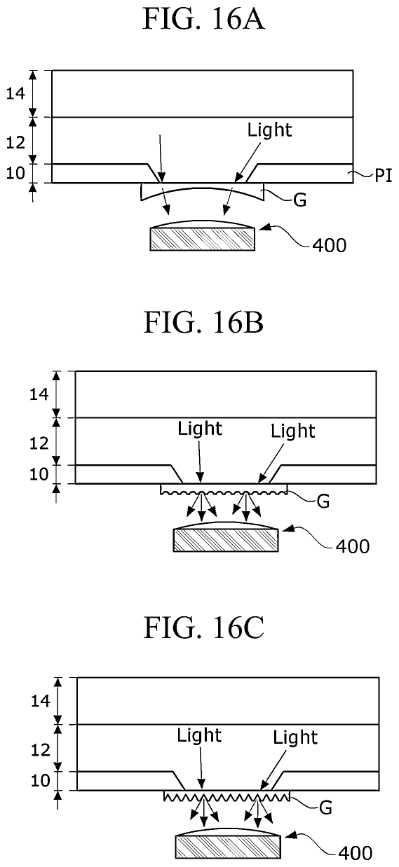

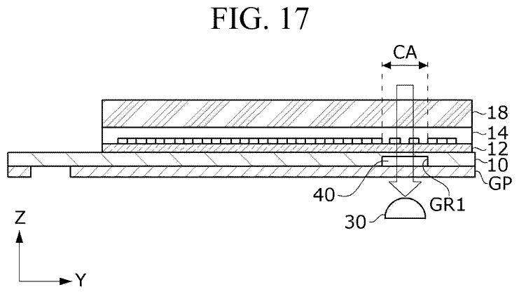

FIGS. 16A-16C are diagrams illustrating various example shapes of glass disposed on a display panel according to example embodiments of the present disclosure.

As illustrated in FIG. 16A, the glass G may be formed in a plano-concave lens shape. Accordingly, the glass G may improve transmissivity while suppressing total reflection of obliquely incident light. For example, the glass G may include a first surface in contact with the substrate PI and a second surface opposite to the first surface. Here, the first surface may be a flat surface, and the second surface, which is the rear surface, may be formed as a curved surface with its center more recessed than its edges. Further, the second surface may be a surface disposed to face the lens 30.

As illustrated in FIGS. 16B and 16C, the glass G may be formed in a shape in which a pattern is formed on the second surface. In this case, the first surface may be flat surface.

The pattern may improve transmissivity while suppressing total reflection of obliquely incident light by forming a micro lens array. Here, in the micro lens array, depressions and protrusions may be alternately disposed.

As shown in FIG. 16B, the pattern may be formed in a micro-lens shape in which a plurality of arch-shaped curved surfaces are disposed.

As shown in FIG. 16C, the pattern may be formed in the form of an inverted prism sheet. For example, the pattern may be formed to have a prism pattern having a triangular cross section at a regular interval.

### Second Example Embodiment

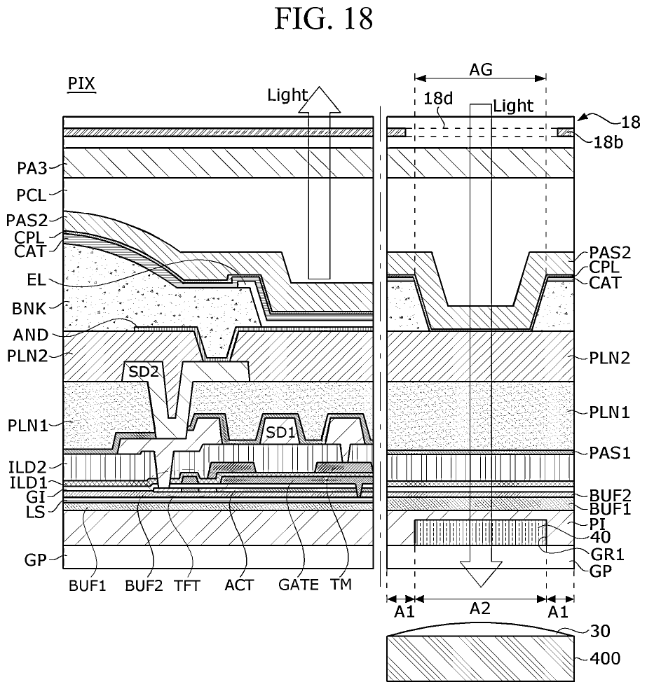

FIG. 17 is a diagram schematically illustrating a display device according to a second example embodiment of the present disclosure, and FIG. 18 is a diagram illustrating example cross-sectional structures of a pixel area and a light-transmission area of the display device according to the second example embodiment of the present disclosure.

In a comparison between the display devices according to the first and second example embodiments with reference to FIGS. 17 and 18, the display device according to the second example embodiment is different from the display device according to the first example embodiment in that the groove GR1 formed in the substrate PI is provided as a high-transmittance structure that improves a light-transmittance property in the second display area CA. Also, the shape of the glass plate GP in the second example embodiment is different from that in the first example embodiment.

Hereinafter, in describing the display device according to the second example embodiment, configurations identical or similar to those of the display device according to the first example embodiment may be denoted by the same reference numerals, and thus detailed description thereof may be omitted.

As shown in FIG. 17, the display device according to the second example embodiment of the present disclosure may include a circuit layer 12 disposed on a substrate 10, a light emitting element layer 14 disposed on the circuit layer 12, a polarizing plate 18 disposed on the light emitting element layer 14, and a groove GR1 concavely formed on the substrate 10 in the Z-axis direction. In addition, the display device according to the second example embodiment may further include a light-transmittance member 40 disposed inside the groove GR1. Here, the light-transmittance member 40 may be an organic material or an inorganic material.

Accordingly, the display device according to the second example embodiment may implement a high-transmittance structure that improves a light-transmittance property through the groove GR1. In this case, the groove GR1 in the substrate 10 may be formed entirely or partially in the second display area CA. For example, since the groove GR1 is disposed to overlap with the light-transmission area AG and reduces the thickness of the substrate 10 in the Z-axis direction, the adverse effect of the substrate 10 on the light transmissivity may be reduced in the second display area CA. Accordingly, the groove GR1 may improve transmissivity of light introduced through the second display area CA. In this case, the light transmissivity may be further improved by forming the substrate 10 as a single layer to further reduce the thickness of the substrate 10 in the Z-axis direction. Further, the reduced thickness of the substrate 10 may improve the flexibility of the display panel 100. Here, the groove GR1 may be referred to as a substrate groove or a second high-transmittance structure.

In addition, the display device according to the second example embodiment may further include a glass plate GP disposed on the lower portion of the substrate 10. Accordingly, the light-transmittance member 40 may be deposited on a portion of the upper side of the glass plate GP, and the substrate 10 may be disposed to cover the light-transmittance member 40, such that the groove GR1 formed in the lower portion of the substrate 10 and the light-transmittance member 40 disposed in the groove GR1 may be implemented in the display device according to the second example embodiment.

Further, the substrate 10 may be formed to have a thickness of 5 μm or less in the Z-axis direction through a dry etching process. In addition, the reduction of the thickness of the substrate 10 through this process may improve the flexibility of the display panel 100 and may further improve the light transmissivity. As the light transmissivity is improved, color balance may also be improved.

Therefore, by implementing the groove GR1 and the single PI substrate structure, the display device according to the second example embodiment may improve light transmissivity by about 3.7% or more compared to the comparative example based on the light having a wavelength of 555 nm.

As illustrated in FIGS. 13 and 18, in the pixel area PIX of the display device according to the second example embodiment, the circuit layer 12, the light emitting element layer 14, and other layers or elements may be stacked on a substrate 10, PI.

As shown in FIG. 18, as in the first example embodiment, a first light-transmission pattern 18d may be formed on the polarizing plate 18 in the light-transmission area AG.

In addition, an opening may be formed in the cathode electrode CAT in the light-transmission area AG as in the first example embodiment.

However, unlike in the display device according to the first example embodiment, a hole is not formed in a portion of the circuit layer 12 in the display device according to the second example embodiment.

Accordingly, the buffer layers BUF1 and BUF2, the gate insulating layer GI, the interlayer insulating layers ILD1 and ILD2, the inorganic insulating layer PAS1, and the planarization layers PLN1 and PLN2 may be disposed on the upper portion of the substrate PI. However, these layers are not necessarily limited thereto.

In addition, a concave groove GR1 may be formed in the lower portion of the substrate PI. The substrate PI may include a first surface in contact with the circuit layer 12 and a second surface opposite to the first surface, and the groove GR1 may be formed on the second surface, as shown for example in FIG. 18.

Due to the groove GR1, the second display area CA of the substrate PI may include a low-transmittance area A1 in which the groove GR1 is not disposed and a high-transmittance area A2 in which the groove GR1 is disposed. In addition, the high-transmittance area A2 may be implemented by stacking the light-transmittance member 40 on a portion of the substrate PI and forming the substrate PI to cover the light-transmittance member 40. Here, the groove GR1 may be formed in a cylindrical shape or a reverse tapered shape having a narrow top and a wide bottom.

Therefore, even if yellowish polyimide is used as the material of the substrate PI, the light transmissivity may be improved by the high-transmittance area A2.

In addition, an organic material or an inorganic material may be disposed inside the groove GR1 to form the light-transmittance member 40. Here, the organic material may include at least one material selected from the group consisting of an epoxy-based material including epoxy, polyimide, polyethylene terephthalate, polycarbonate, polyethylene, and polyacrylate, and an acrylic-based material. In addition, the inorganic material may include at least one material selected from the group consisting of silicon oxide (SiOx), silicon nitride (SiNx), silicon oxynitride (SiON), aluminum oxide (AlO), aluminum nitride (AlON), titanium oxide (TiO₂), zirconium oxide (ZrOx), and zinc oxide (ZnO).

The glass plate GP may be disposed on the lower portion of the substrate PI to support the substrate PI and the light-transmittance member 40.

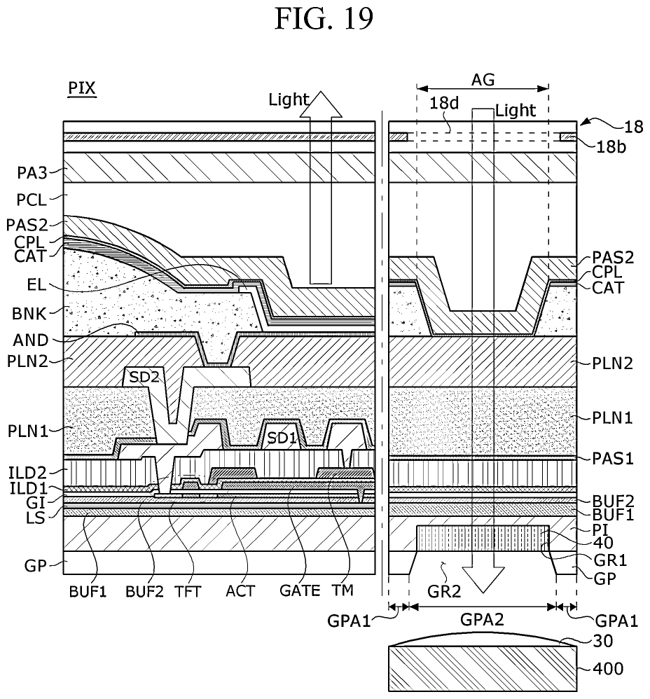

FIGS. 19 to 21 are diagrams illustrating various modified examples of a glass plate disposed in a light-transmission area of the display device according to the second example embodiment of the present disclosure.

As illustrated in FIG. 19, the glass plate GP may include a groove GR2 concavely formed at a lower portion thereof. The groove GR2 may be formed over the entire second display area CA or may be formed to correspond to the light-transmission area AG. As shown in FIG. 19, the groove GR2 of the glass plate GP may be formed to overlap with the groove GR1 formed in the substrate PI. Here, the groove GR2 of the glass plate GP may be referred to as a glass plate groove. Accordingly, the groove GR2 of the glass plate GP may further improve transmissivity of light reaching the lens 30. In addition, the groove GR2 of the glass plate GP may reduce the distance between the lens and the substrate PI, thereby allowing for a more compact display device.

In addition, the groove GR2 of the glass plate GP may be formed to correspond to a shape of the groove GR1 of the substrate PI, and may be formed in a cylindrical shape or a reverse tapered shape having a narrow top and a wide bottom.

The groove GR2 may be formed through an etching process of etching a portion of the glass plate GP. Further, the glass plate GP may include a first glass plate area GPA1 disposed to overlap with the low-transmittance area A1 and a second glass plate area GPA2 disposed to overlap with the high-transmittance area A2 due to the groove GR2.

In this case, if the groove GR1 is formed in the high-transmittance area A2, the thickness of the second glass plate area GPA2 may converge to zero. For example, if the thickness of the second glass plate area GPA2 in the Z-axis direction is 0, the organic or inorganic materials disposed in the groove may be exposed. Even if the thickness of the second glass plate area GPA2 is not 0, since the thickness of the second glass plate area GPA2 is smaller than the thickness of the first glass plate area GPA1, the light transmissivity may be improved in the second glass plate area GPA2.

However, in consideration of the light transmittance property and the fact that a portion of the substrate PI may be disposed to overlap with the groove GR1 formed in the substrate PI to protect the circuit layer 12, it is preferable that the thickness of the second glass plate area GPA2 in the Z-axis direction is 0, and the second glass plate area GPA2 may be provided in the shape of a hole.

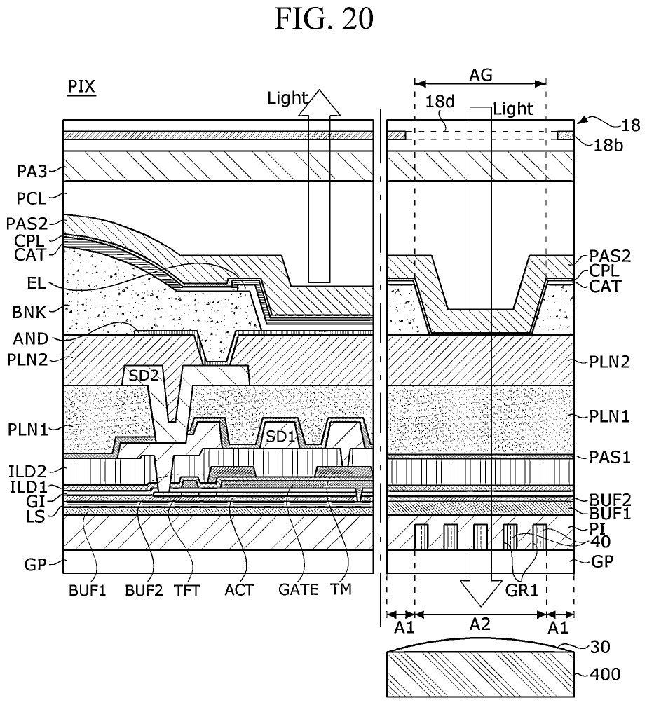

FIG. 20 is a diagram illustrating another example of a groove formed in a substrate of the display device according to the second example embodiment of the present disclosure.

As illustrated in FIG. 20, a plurality of grooves GR1 may be spaced apart from each other at predetermined intervals in the substrate PI.

The plurality of grooves GR1 may be formed at equal intervals or at different intervals on the second surface of the substrate PI. For example, in view of the type of lens 30 and the concentration of light incident on the lens 30, the plurality of grooves GR1 may be disposed on the substrate PI at different intervals.

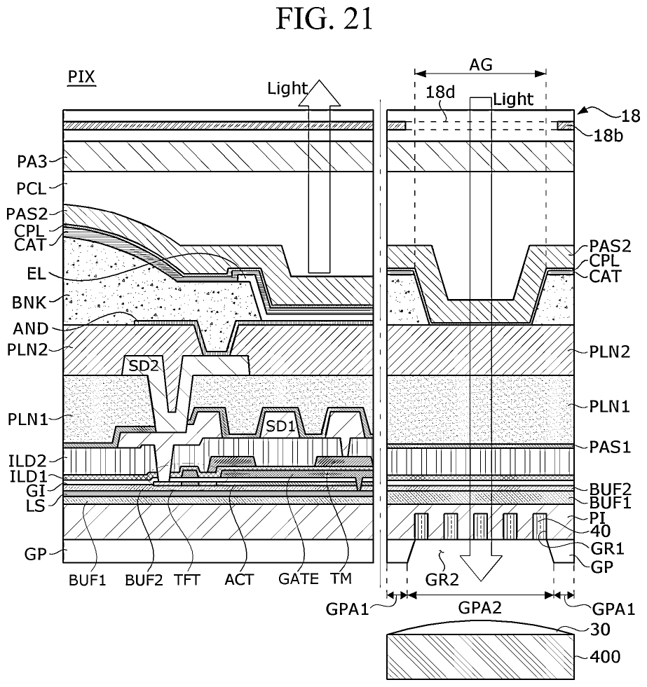

FIG. 21 is a view showing another example of a groove formed in a substrate of the display device and a modified example of a glass plate disposed to correspond to the groove according to the second example embodiment of the present disclosure.

As shown in FIG. 21, a plurality of grooves GR1 may be spaced apart from each other at predetermined intervals in the substrate PI, and a groove GR2 may be concavely formed in the glass plate GP. Here, the groove GR2 of the glass plate GP may be formed to correspond to the plurality of grooves GR1 formed in the substrate PI.

Also, if the groove GR2 is concavely formed in the glass plate GP, a curved surface or a pattern may be formed on a portion of the lower surface of the glass plate GP. Here, the lower surface may be a surface of the glass plate GP disposed to face the lens 30.

A curved surface shown in FIG. 16A may be formed to correspond to the lens 30 on a portion of the lower surface of the glass plate GP. Accordingly, the light transmissivity may be improved by suppressing the total reflection of the light obliquely incident on the glass plate GP.

In addition, the patterns shown in FIG. 16B or 16C may be formed to correspond to the lens 30 on a portion of the lower surface of the glass plate GP. Accordingly, the light transmissivity may be improved by suppressing the total reflection of the light obliquely incident on the glass plate GP.

### Third Example Embodiment

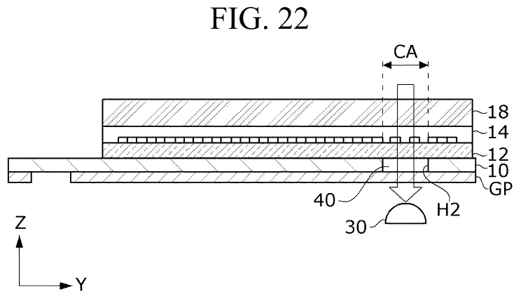

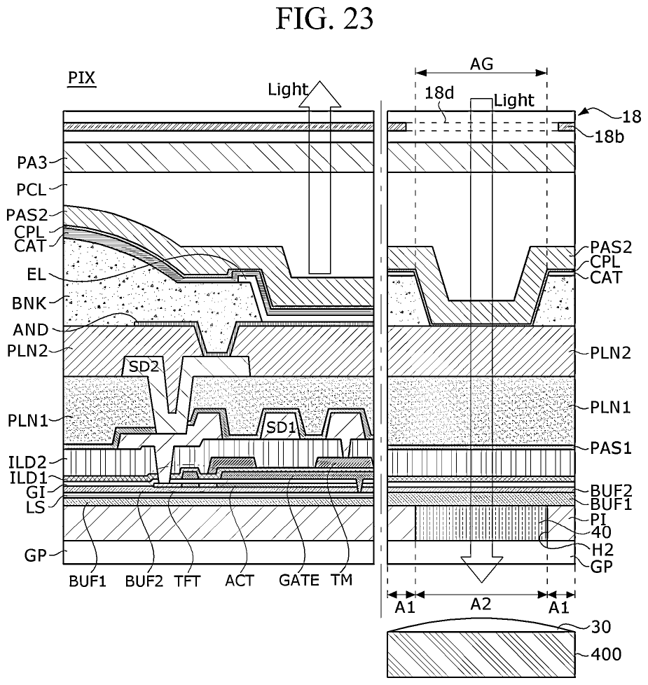

FIG. 22 is a diagram schematically illustrating a display device according to a third example embodiment of the present disclosure, and FIG. 23 is a diagram illustrating example cross-sectional structures of a pixel area and a light-transmission area of the display device according to the third example embodiment of the present disclosure.

In a comparison between the display devices according to the second and third example embodiments with reference to FIGS. 22 and 23, the display device according to the third example embodiment is different from the display device according to the second example embodiment in that the hole H2 formed in the substrate PI is provided as a high-transmittance structure to improve a light-transmittance property instead of the groove GR1 of the display device according to the second example embodiment.

Hereinafter, in describing the display device according to the third example embodiment, configurations identical or similar to those of the display device according to the second example embodiment may be denoted by the same reference numerals, and detailed description thereof may be omitted.

As illustrated in FIG. 22, the display device according to the second example embodiment of the present disclosure may include a circuit layer 12 disposed on a substrate 10, a light emitting element layer 14 disposed on the circuit layer 12, a polarizing plate 18 disposed on the light emitting element layer 14, and a hole H2 formed through the substrate 10 in the Z-axis direction. In addition, the display device according to the third example exemplary embodiment may further include a light-transmittance member 40 disposed inside the hole H2. Here, the light-transmittance member 40 may be an organic material or an inorganic material.

Accordingly, the display device according to the third example embodiment may implement a high-transmittance structure that improves the light-transmittance property through the hole H2. In this case, the hole H2 may be formed in the substrate 10 entirely or partially in the second display area CA. For example, the hole H2 may be disposed to overlap with the light-transmission area AG. Accordingly, the hole H2 may improve transmissivity of light introduced through the second display area CA. In this case, the light transmissivity may be further improved by forming the substrate 10 as a single layer to further reduce the thickness of the substrate 10 in the Z-axis direction. Further, the reduced thickness of the substrate 10 may improve the flexibility of the display panel 100. Here, the hole H2 may be referred to as a second hole or a third high-transmittance structure.

In addition, the display device according to the third example embodiment may further include a glass plate GP disposed on the lower portion of the substrate 10. Accordingly, the light-transmittance member 40 may be deposited on a portion of the upper side of the glass plate GP, and the substrate 10 may be disposed to cover the side surface of the light-transmittance member 40, such that the hole H2 formed in the substrate 10 and the light-transmittance member 40 disposed in the hole H2 may be implemented in the display device according to the third example embodiment.

During the deposition process of the substrate 10, even if a portion of the substrate 10 covers the light-transmittance member 40, a substrate material such as polyimide remaining on the light-transmittance member 40 may be removed through a dry etching process to implement the hole H2.

In this case, the substrate 10 may have a thickness of 5 μm or less in the Z-axis direction through the dry etching process. In addition, the reduction of the thickness of the substrate 10 through this process may improve the flexibility of the display panel 100 and at the same time further improve the light transmissivity. Accordingly, the color balance may also be improved.

Therefore, by implementing the hole H2 and the single PI substrate structure, the display device according to the third example embodiment may improve light transmissivity by about 20.65% or more compared to the comparative example based on the light having a wavelength of 555 nm.

As shown in FIGS. 13 and 23, in the pixel area PIX of the display device according to the example third embodiment, a circuit layer 12, a light emitting element layer 14, and the like may be stacked on a substrate PI 10.

As illustrated in FIG. 23, a first light-transmission pattern 18d may be formed in the polarizing plate 18 in the light-transmission area AG as in the first example embodiment.

In addition, an opening may be formed in a cathode electrode CAT in the light-transmission area AG also as in the first example embodiment.

However, unlike the display device according to the first example embodiment, the display device according to the third example embodiment is different in that a hole is not formed in a portion of the circuit layer 12.

Accordingly, the buffer layers BUF1 and BUF2, the gate insulating layer GI, the interlayer insulating layers ILD1 and ILD2, the inorganic insulating layer PAS1, and planarization layers PLN1 and PLN2 may be disposed on the upper portion of the substrate PI in the light-transmission area AG. However, these layers are not necessarily limited thereto.

Also, as the hole H2 is formed in the substrate PI, the second display area CA of the substrate PI may include a low-transmittance area A1 in which the hole H2 is not disposed and a high-transmittance area A2 in which the hole H2 is disposed. In addition, the high-transmittance area A2 may be implemented by stacking the light-transmittance member 40 on a portion of the substrate PI and forming the substrate PI to cover the sides of the light-transmittance member 40. Here, the hole H2 may be formed in a cylindrical shape or a reverse tapered shape having a narrow top and a wide bottom.

Therefore, even if yellowish polyimide is used as the material of the substrate PI, the light transmissivity may be improved by the high-transmittance area A2.

In addition, an organic material or an inorganic material may be disposed inside the hole H2. Here, the organic material may include at least one material selected from the group consisting of an epoxy-based material including epoxy, polyimide, polyethylene terephthalate, polycarbonate, polyethylene, and polyacrylate, and an acrylic-based material. In addition, the inorganic material may include at least one material selected from the group consisting of silicon oxide (SiOx), silicon nitride (SiNx), silicon oxynitride (SiON), aluminum oxide (AlO), aluminum nitride (AlON), titanium oxide (TiO₂), zirconium oxide (ZrOx), and zinc oxide (ZnO).

The glass plate GP may be disposed on the lower portion of the substrate PI to support the substrate PI and the light-transmittance member 40.

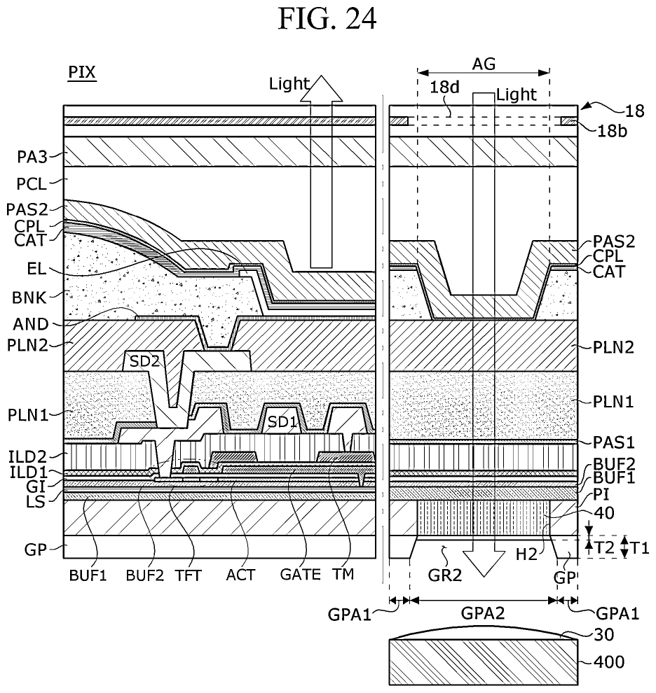

FIG. 24 is a diagram illustrating a modified example of a glass plate GP disposed in a light-transmission area of the display device according to the third example embodiment of the present disclosure.

As shown in FIG. 24, the glass plate GP may include a groove GR2 concavely formed at a lower portion thereof. The groove GR2 may be formed over the entire second display area CA or may be formed to correspond to the light-transmission area AG. As shown in FIG. 24, the groove GR2 of the glass plate GP may be formed to overlap with the hole H2 formed in the substrate PI. Accordingly, the groove GR2 of the glass plate GP may improve transmissivity of light reaching the lens 30 and may reduce the distance between the lens and the substrate PI, thereby allowing for a more compact display device.

In addition, the groove GR2 of the glass plate GP may be formed to correspond to the hole H2 of the substrate PI, and may be formed in a cylindrical shape or a reverse tapered shape having a narrow top and a wide bottom.

The groove GR2 may be formed through an etching process of etching a portion of the glass plate GP. Further, the glass plate GP may include a first glass plate area GPA1 and a second glass plate area GPA2 due to the groove GR2.

If the hole H2 is formed in the high-transmittance area A2, the glass plate GP may be formed to have the thickness T2 in the second glass plate area GPA2 smaller than the thickness T1 in the first glass plate area GPA1 to prevent damage caused by an etching process. Accordingly, the light transmissivity in the second glass area GPA2 may be improved. Here, in consideration of the etchant and the material of the light-transmittance member 40, the second glass area GPA2 of the display device according to the third exemplary embodiment may be formed to expose the hole H2. That is, the second glass area GPA2 may be provided in the shape of a hole.

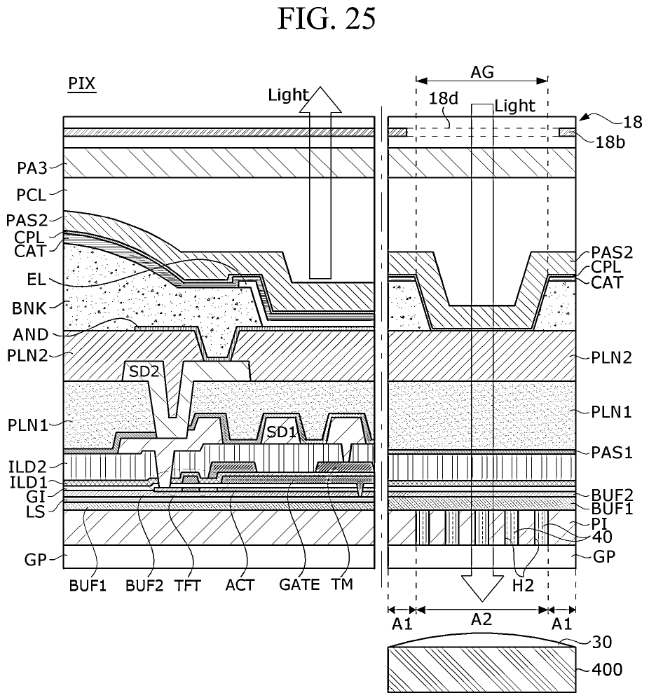

FIG. 25 is a diagram illustrating another example of a hole H2 formed in a substrate of the display device according to the third example embodiment of the present disclosure.

As illustrated in FIG. 25, a plurality of holes H2 may be disposed to be spaced apart from each other at predetermined intervals in the substrate PI.

The plurality of holes H2 may be formed at equal intervals or at different intervals on the second surface of the substrate PI. For example, in view of the type of lens 30 and the concentration of light incident on the lens 30, the plurality of holes H2 may be disposed on the substrate PI at different intervals.

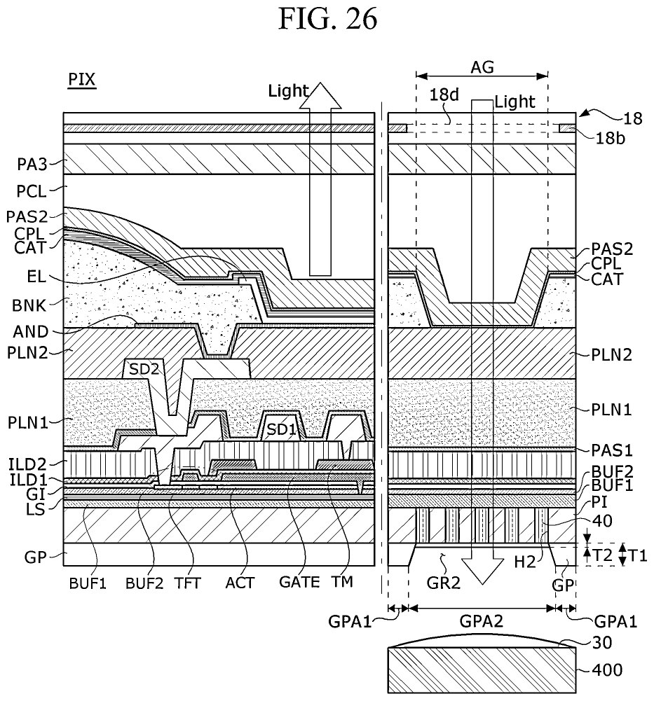

FIG. 26 is a view showing another example of a hole H2 formed in a substrate of the display device and a modified example of a glass plate GP disposed to correspond to the hole H2 according to the third example embodiment of the present disclosure.

As illustrated in FIG. 26, a plurality of holes H2 may be spaced apart from each other at predetermined intervals in the substrate PI, and a groove GR2 may be concavely formed in the glass plate GP. Here, the groove GR2 of the glass plate GP may be formed to correspond to the plurality of holes H2 formed in the substrate PI.

Meanwhile, if the groove GR2 is concavely formed in the glass plate GP, a curved surface or a pattern may be formed on a portion of the lower surface of the glass plate GP.

On the portion of the lower surface of the glass plate GP, the curved surface shown in FIG. 16A may be formed to correspond to the lens 30, or a pattern shown in FIG. 16B or 16C may be formed to correspond to the lens 30.

### Fourth Example Embodiment

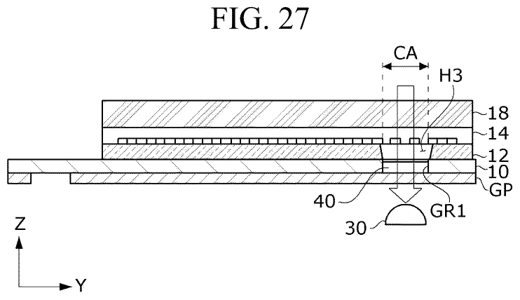

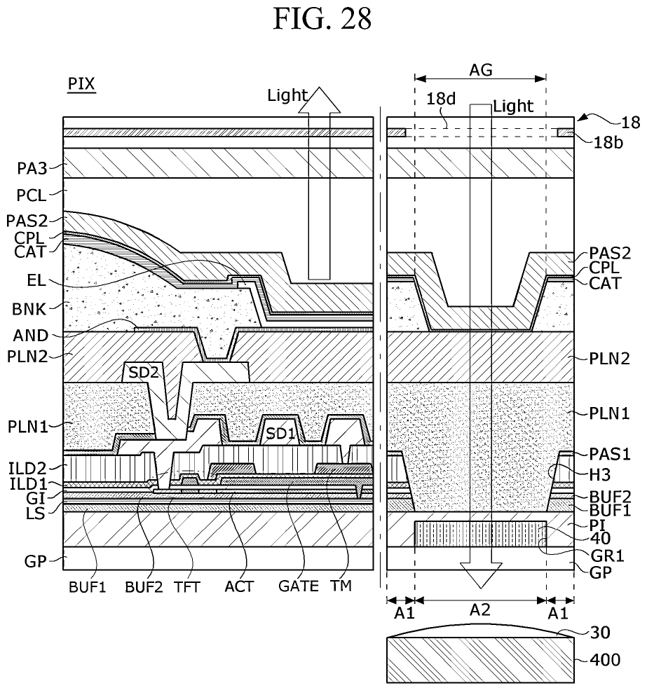

FIG. 27 is a diagram schematically illustrating a display device according to a fourth example embodiment of the present disclosure, and FIG. 28 is a diagram illustrating example cross-sectional structures of a pixel area and a light-transmission area of the display device according to the fourth example embodiment of the present disclosure.

In a comparison between the display devices according to the first and fourth example embodiments with reference to FIGS. 27 and 28, the display device according to the fourth example embodiment is different from the display device according to the first example embodiment in that the groove GR1 may be formed in the substrate PI as a high-transmittance structure that improves the light-transmittance property in the second display area CA. Additionally, among other differences, the shape of the glass plate GP in the fourth example embodiment may be different from that in the first example embodiment.

In a comparison between the display devices according to the second and fourth example embodiments with reference to FIGS. 27 and 28, the display device according to the fourth example embodiment is different from the display device according to the second example embodiment in that a hole H3 may be formed in a portion of the circuit layer 12 in the second display area CA as a high-transmittance structure that improves the light-transmittance property. Additionally, among other differences, the hole H3 may be spaced apart from the groove GR1 in the fourth example embodiment.

Hereinafter, in describing the display device according to the fourth example embodiment, configurations identical or similar to those of the display device according to the first to third example embodiments may be denoted by the same reference numerals, and thus detailed description thereof may be omitted.

As illustrated in FIG. 27, a display device according to a fourth example embodiment of the present disclosure may include a circuit layer 12 disposed on a substrate 10, a light emitting element layer 14 disposed on the circuit layer 12, a polarizing plate 18 disposed on the light emitting element layer 14, and a hole H3 formed to penetrate a portion of the circuit layer 12 in the Z-axis direction. In this case, the hole H3 may be formed to have a tapered cross section, and a transparent organic or inorganic material may be disposed therein. The hole H3 may be referred to as a third hole.

In addition, the display device according to the fourth example embodiment may include a groove GR1 concavely formed on a lower portion of the substrate PI. The groove GR1 may be formed in the substrate PI over the entire second display area CA or to correspond to the light light-transmission area AG. Further, the groove GR1 may be disposed to be spaced apart from the hole H3 in the Z-axis direction by a portion of the substrate PI 10. In this case, the light transmissivity may be further improved by forming the substrate PI 10 as a single layer to further reduce the thickness of the substrate 10 in the Z-axis direction. Further, the reduced thickness of the substrate PI 10 may improve the flexibility of the display panel 100.

Accordingly, the display device according to the fourth example embodiment of the present disclosure may implement a high-transmittance structure that improves light transmittance property through the hole H3 and the groove GR1. Thus, the hole H3 and the groove GR1 may be referred to as a fourth high-transmittance structure.

In addition, the display device according to the fourth example embodiment may further include a light-transmittance member 40 disposed inside the groove GR1. Here, the light-transmittance member 40 may be an organic material or an inorganic material.

Therefore, by implementing the hole H3, the groove GR1, and the single PI substrate structure, in the display device according to the fourth example embodiment, the light transmissivity may be improved by about 22% compared to the light transmissivity of the comparative example based on the light having a wavelength of 555 nm.

As illustrated in FIGS. 13 and 28, in the pixel area PIX of the display device according to the fourth example embodiment, the circuit layer 12, the light emitting element layer 14, and other layers or elements may be stacked on a substrate PI 10.

As illustrated in FIG. 28, a first light-transmission pattern 18d may be formed on the polarizing plate 18 in the light-transmission area AG.

In addition, an opening (a first opening) may be formed in the cathode electrode CAT in the light-transmission area AG.

A hole H3 penetrating a portion of the circuit layer 12 may be formed in the light-transmission area AG. Here, the hole H3 may be disposed to overlap with the first opening.

Since the hole H3 is formed to penetrate the buffer layer and the plurality of insulating layers of the circuit layer 12, the interface between the plurality of layers is removed in the light-transmission area AG due to the hole H3, such that the light transmissivity of the light-transmission area AG may be improved.

In addition, a transparent organic or inorganic material may be disposed inside the hole H3. Here, the organic or inorganic material may be the same material as one or more of the layers constituting the first pixel or the second pixel, such as, a first buffer layer BUF1, a second buffer layer BUF2, a gate insulating layer GI, a first interlayer insulating layer ILD1, a second interlayer insulating layer ILD2, a first planarization layer PLN1, a second planarization layer PLN2, or may be a different material. In this case, the organic material and/or inorganic material may be formed through a process of filling the inside of the hole H3.

As shown in FIG. 28, the same material (the same organic insulating material) as the first planarization layer PLN1 of the pixel area PIX disposed in the second display area CA may be disposed inside the hole H3. Here, the material disposed inside the hole H3 may be made of an organic insulating material like the first planarization layer PLN1 as an example but is not necessarily limited thereto. For example, in some cases, the material disposed inside the hole H3 may be an inorganic insulating material.

In addition, the hole H3 may be formed to have a tapered vertical cross section. As shown in FIG. 28, the hole H3 may be formed in a positively tapered shape having a wide top and a narrow bottom.

As shown in FIG. 28, the substrate PI may include a first surface in contact with the circuit layer 12 and a second surface opposite to the first surface. The groove GR1 may be formed on the second surface of the substrate PI.

Due to the groove GR1, the second display area CA of the substrate PI may include a low-transmittance area A1 in which the groove GR1 is not disposed and a high-transmittance area A2 in which the groove GR1 is disposed. Further, the high-transmittance area A2 may be implemented by stacking the light-transmittance member 40 on a portion of the glass plate GP and forming the substrate PI to cover the light-transmittance member 40. Here, the groove GR1 may be formed in a cylindrical shape or a reverse tapered shape having a narrow top and a wide bottom.

Therefore, even if yellowish polyimide is used as the material of the substrate PI, the light transmissivity may be improved by the high-transmittance area A2.

In addition, an organic material or an inorganic material may be disposed inside the groove GR1. Here, the organic material may include at least one material selected from the group consisting of an epoxy-based material including epoxy, polyimide, polyethylene terephthalate, polycarbonate, polyethylene, and polyacrylate, and an acrylic-based material. In addition, the inorganic material may include at least one material selected from the group consisting of silicon oxide (SiOx), silicon nitride (SiNx), silicon oxynitride (SiON), aluminum oxide (AlO), aluminum nitride (AlON), titanium oxide (TiO₂), zirconium oxide (ZrOx), and zinc oxide (ZnO).

Also, the glass plate GP may be disposed on the lower portion of the substrate PI to support the substrate PI and the light-transmittance member 40.

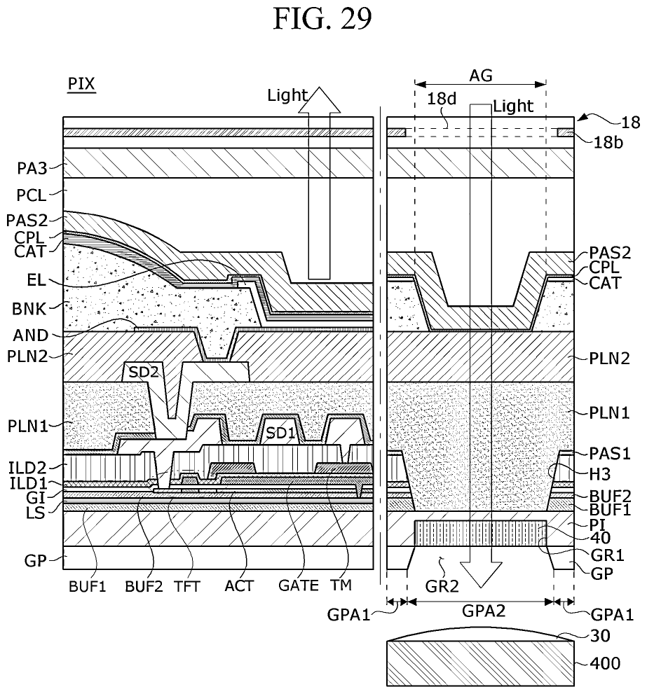

FIG. 29 is a diagram illustrating a modified example of a glass plate disposed in a light-transmission area of the display device according to the fourth example embodiment of the present disclosure.

As illustrated in FIG. 29, the glass plate GP may include a groove GR2 concavely formed at a lower portion thereof. The groove GR2 may be formed in the glass plate GP over the entire second display area CA or may be formed to correspond to the light-transmission area AG. As shown in FIG. 29, the groove GR2 of the glass plate GP may be formed to overlap with the groove GR1 formed in the substrate PI. Accordingly, the groove GR2 of the glass plate GP may improve transmissivity of light reaching the lens 30. In addition, the groove GR2 of the glass plate GP may reduce the distance between the lens and the substrate PI, thereby allowing for a more compact display device.

In addition, the groove GR2 of the glass plate GP may be formed to correspond to the groove GR1 of the substrate PI, and may be formed in a cylindrical shape or a reverse tapered shape having a narrow top and a wide bottom. In this case, the groove GR2 may be formed through an etching process of etching a portion of the glass plate GP. Further, the glass plate GP may include a first glass plate area GPA1 disposed to overlap with the low-transmittance area A1 and a second glass plate area GPA2 disposed to overlap with the high-transmittance area A2 due to the groove GR2. Here, if the groove GR1 is formed in the high-transmittance area A2, the thickness of the second glass plate area GPA2 may converge to zero, but is not necessarily limited thereto. For example, in consideration of the light-transmittance property and the fact that a portion of the substrate PI may be disposed to overlap with the groove GR1 formed in the substrate PI to protect the circuit layer 12, it is preferable that the thickness of the second glass area GPA2 in the Z-axis direction be 0, and the second glass plate area GPA2 may be provided in the shape of a hole.

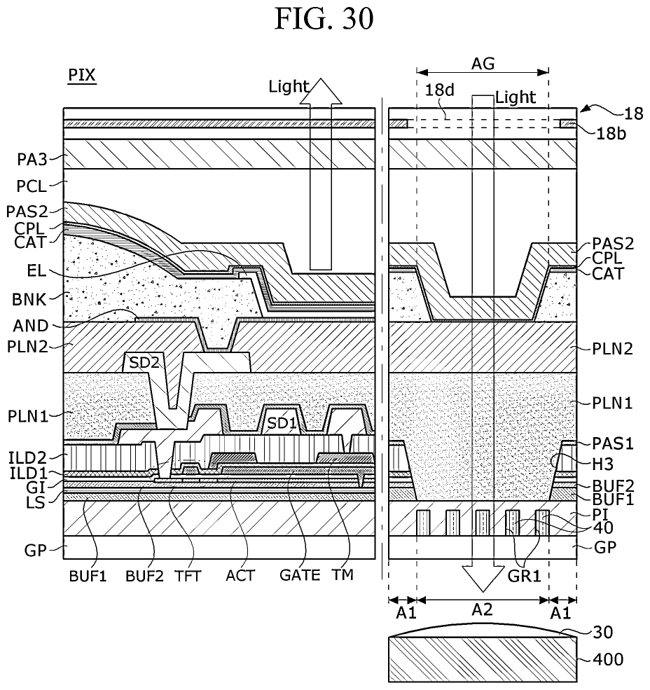

FIG. 30 is a diagram illustrating another example of a groove GR1 formed in a substrate PI of the display device according to the fourth example embodiment of the present disclosure;

As shown in FIG. 30, a plurality of grooves GR1 may be spaced apart from each other at predetermined intervals in the substrate PI.

The plurality of grooves GR1 may be formed at equal intervals or at different intervals on the second surface. For example, in view of the type of lens 30 and the concentration of light incident on the lens 30, the plurality of grooves GR1 may be disposed on the substrate PI at different intervals.

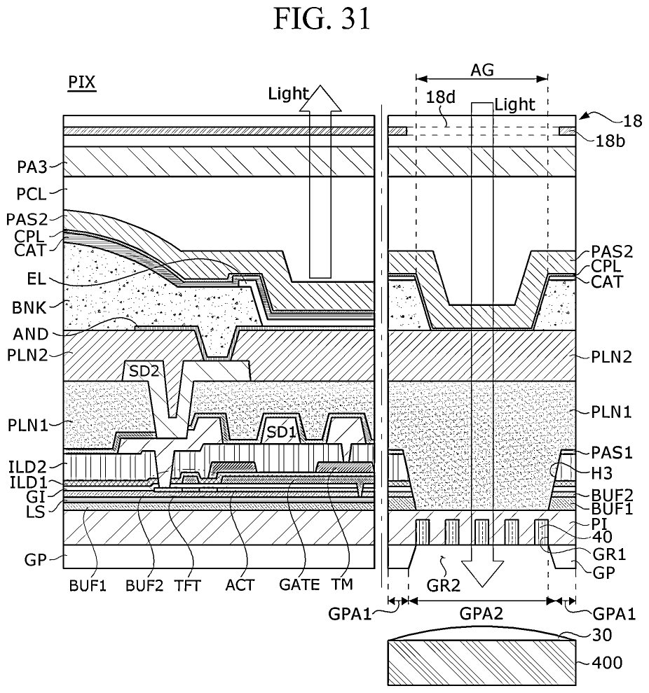

FIG. 31 is a view showing another example of the groove GR1 formed in the substrate PI of the display device and a modified example of the glass plate GP disposed to correspond to the groove GR1 according to the fourth example embodiment of the present disclosure.

As shown in FIG. 31, a plurality of grooves GR1 may be disposed to be spaced apart from each other at predetermined intervals in the substrate PI, and a groove GR2 may be concavely formed in the glass plate GP. Here, the groove GR2 of the glass plate GP may be formed to correspond to the plurality of grooves GR1 formed in the substrate PI.

Also, if the groove GR2 is concavely formed in the glass plate GP, a curved surface or a pattern may be formed on a portion of the lower surface of the glass plate GP. Here, the lower surface may be a surface of the glass plate GP disposed to face the lens 30 and may form a portion of the groove GR2.

On a portion of the lower surface of the glass plate GP, a curved surface shown in FIG. 16A may be formed to correspond to the lens 30. Accordingly, the light transmissivity may be improved while suppressing total reflection of the light obliquely incident on the glass plate GP.

In addition, patterns shown in FIG. 16B or 16C may be formed to correspond to the lens 30 on a part of the lower surface of the glass plate GP. Accordingly, the light transmissivity may be improved while suppressing total reflection of light obliquely incident on the glass plate GP.

In summary, the display device according to example embodiments of the present disclosure may improve the light transmissivity by using one or more of the above-described high-transmittance structures.

In addition, the display device according to example embodiments of the present disclosure may further improve the light transmissivity through the PI substrate structure made of the single layer.

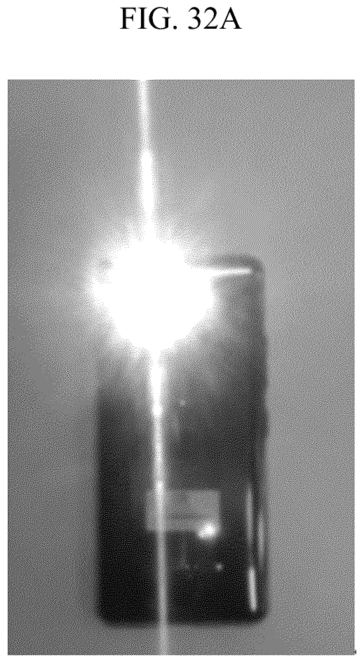

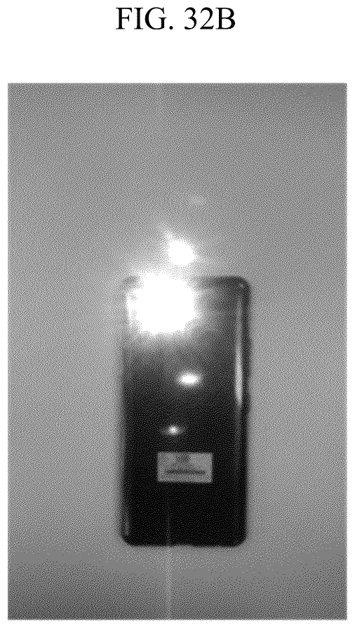

FIGS. 32A and 32B are pictures respectively illustrating a flare of a display device according to a comparative example and a flare of a display device according to an example embodiment of the present disclosure.

As shown in FIG. 32A, the display device according to the comparative example includes a double PI substrate structure. Since a remaining film of a sacrificial layer is formed by a laser lift-off (LLO) process, a flare is observed in the vertical direction (Y axial direction).

In contrast, since the display device according to an example embodiment of the present disclosure includes a single PI substrate structure and the laser lift-off (LLO) process is not performed, the flare formed in the vertical direction is not observed (or a significantly reduced flare is observed) as shown in FIG. 32B.

That is, since the display device according to an example embodiment of the present disclosure does not implement a laser lift-off (LLO) process, quality may be improved. Furthermore, since the laser lift-off (LLO) process is not performed, the substrate PI 10 of a single PI substrate structure may be implemented such that the light transmissivity of the substrate PI 10 may be improved.

In addition, the display device according to example embodiments of the present disclosure may improve the light transmissivity while suppressing total reflection of obliquely incident lights by implementing a curved surface or pattern formed on the glass G or the glass plate GP.

The objects to be achieved by the present disclosure, the means for achieving the objects, and effects of the present disclosure described above do not specify essential features of the claims. Thus, the scope of the claims is not limited to such objects, means for achieving the objects, or effects of the present disclosure or to the example embodiments detailed above.

Although example embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

Reference Sign Description

| | |
|---|---|
| 100: | display panel |
| 200: | host system |
| 300: | drive IC |
| 400: | camera module |
| DA: | first display area |
| CA: | second display area |
| AG: | light-transmission area |
| G: | glass |
| GP: | glass plate |
| BP: | back plate |
| PI: | substrate |
| PLN: | planarization layer |
| PLN1: | first planarization layer |
| PLN2: | second planarization layer |

What is claimed is:

1. A display device, comprising:
a display panel including:
a first display area having a plurality of first pixels; and
a second display having a plurality of second pixels and a light-transmission area between the second pixels; and
a sensor or an optical element under the display panel and overlapping with the second display area of the display panel,
wherein the display panel includes:
a substrate;
a circuit layer on the substrate and having a buffer layer and a plurality of insulating layers; and
a light emitting element layer on the circuit layer, and
wherein the second display area includes a hole penetrating the substrate, the buffer layer, and the plurality of insulating layers, and a glass disposed to cover the hole, and
wherein the glass is disposed in the second display area.

2. The display device of claim 1, further comprising a back plate disposed at a bottom surface of the substrate to cover a bottom surface of the glass.

3. The display device of claim 1, wherein:
the glass includes a first surface in contact with the substrate and a second surface opposite to the first surface and facing the sensor or the optical element, and
the second surface includes a predetermined pattern or has a concave profile.

4. The display device of claim 1, wherein:
the circuit layer further includes a first planarization layer on the plurality of insulating layers, and
a same material forming the first planarization layer is disposed in the hole.

5. The display device of claim 1, wherein the hole has a tapered cross section with a wider opening at a top of the hole than at a bottom of the hole.

6. The display device of claim 1, further comprising a glass plate at the bottom surface of the substrate.

7. The display device of claim 6, wherein the glass plate includes a second groove penetrating at least a bottom surface of the glass plate in the second display area, the second groove overlapping with the hole.

8. The display device of claim 1, wherein the substrate is formed of one single layer.

9. The display device of claim 1, wherein the sensor or the optical element is an image sensor or a lens of a camera module.

10. The display device of claim 1, wherein a resolution of the second pixels in the second display area is lower than a resolution of the first pixels in the first display area.

11. A display device, comprising:
a display panel including:
a first display area having a plurality of first pixels; and
a second display area having a plurality of second pixels and a light-transmission area between the second pixels; and
a sensor or an optical element under the display panel and overlapping with the second display area of the display panel,
wherein the display panel includes:
a substrate including a low-transmittance area and a high-transmittance area having higher light transmissivity than the low-transmittance area in the second display area, the substrate having a hole or at least one first groove penetrating at least a bottom surface of the substrate in the high-transmittance area;
a circuit layer on the substrate; and
a light emitting element layer on the circuit layer.

12. The display device of claim 11, wherein:
the display panel further includes an organic material or an inorganic material in the hole or the at least one first groove of the substrate,
the organic material includes at least one of an epoxy-based material including epoxy, polyimide, polyethylene terephthalate, polycarbonate, polyethylene, polyacrylate, and an acrylic-based material, and
the inorganic material includes at least one of silicon oxide (SiOx), silicon nitride (SiNx), silicon oxynitride (SiON), aluminum oxide (AlO), aluminum nitride (AlON), titanium oxide (TiO₂), zirconium oxide (ZrOx), and zinc oxide (ZnO).

13. The display device of claim 11, further comprising a glass plate at the bottom surface of the substrate between the substrate and the sensor or the optical element.

14. The display device of claim 13, wherein the glass plate includes:
a first glass plate area overlapping with the low-transmittance area; and
a second glass plate area overlapping with the high-transmittance area and having a second groove penetrating at least a bottom surface of the glass plate, the second glass plate area having a smaller thickness than the first glass plate area.

15. The display device of claim 13, wherein the glass plate includes:
a first glass plate area overlapping with the low-transmittance area; and
a second glass plate area overlapping with the high-transmittance area and having a hole through the glass plate, the second glass area having a minimum thickness of 0.

16. The display device of claim 11, wherein the substrate is formed of one single layer.

17. A display device, comprising:
a display panel including:
a first display area having a plurality of first pixels; and
a second display having a plurality of second pixels and a light-transmission area between the second pixels; and
a sensor or an optical element under the display panel and overlapping with the second display area of the display panel,
wherein the display panel includes:
a substrate;
a circuit layer on the substrate and having a buffer layer and a plurality of insulating layers; and
a light emitting element layer on the circuit layer, and
wherein the second display area includes a hole penetrating the buffer layer, and the plurality of insulating layers, and
wherein the substrate has one or more first grooves penetrating a bottom surface of the substrate, the one or more first grooves overlapping with the hole.

18. The display device of claim 17, wherein:
the substrate covers the hole at a top surface of the substrate, and
a portion of the substrate is disposed between the hole and the one or more first grooves so that the hole is spaced apart from the one or more first grooves.

19. The display device of claim 17, wherein:
the display panel further includes an organic material or an inorganic material in the one or more first grooves of the substrate,
the organic material includes at least one of an epoxy-based material including epoxy, polyimide, polyethylene terephthalate, polycarbonate, polyethylene, polyacrylate, and an acrylic-based material, and
the inorganic material includes at least one of silicon oxide (SiOx), silicon nitride (SiNx), silicon oxynitride (SiON), aluminum oxide (AlO), aluminum nitride (AlON), titanium oxide (TiO₂), zirconium oxide (ZrOx), and zinc oxide (ZnO).

20. The display device of claim 17, further comprising a glass plate at the bottom surface of the substrate, and
wherein the glass plate includes a second groove penetrating at least a bottom surface of the glass plate in the second display area, the second groove overlapping with the hole and the one or more first grooves.
